(19) United States
(12) Patent Application Publication
(10) Pub. No.: US 2024/0014313 A1
(43) Pub. Date: Jan. 11, 2024

(54) SEMICONDUCTOR DEVICE

(71) Applicant: ROHM CO., LTD., Kyoto-shi (JP)

(72) Inventor: Casey CLENDENNEN, Kyoto-shi (JP)

(73) Assignee: ROHM CO., LTD., Kyoto-shi (JP)

(21) Appl. No.: 18/473,344

(22) Filed: Sep. 25, 2023

Related U.S. Application Data
(63) Continuation of application No. PCT/JP2022/006617, filed on Feb. 18, 2022.

(30) Foreign Application Priority Data
Mar. 26, 2021 (JP) 2021-053752

(51) Int. Cl. H01L 29/78; H01L 29/06; H01L 29/40

(52) U.S. Cl. CPC H01L 29/7805; H01L 29/0696; H01L 29/407; H01L 29/7813

(57) ABSTRACT

The semiconductor device includes a chip which has a main surface, a first region of a first conductivity type which is formed in a surface layer portion of the main surface, a second region of a second conductivity type which is formed in a surface layer portion of the first region, a trench separation structure which penetrates through the second region, surrounds an interior of the second region, and demarcates an inner region at an inner side of the second region and an outer region at an outer side of the second region in the main surface, a trench gate structure which is formed in the inner region, an inner diode which includes the first region and the second region that are positioned in the inner region, and an outer diode which includes the first region and the second region that are positioned in the outer region.

### CROSS-REFERENCE TO RELATED APPLICATIONS

The present application is a continuation of International Application No. PCT/JP2022/006617, filed Feb. 18, 2022, which corresponds to Japanese Patent Application No. 2021-053752 filed in the Japan Patent Office on Mar. 26, 2021, and the entire disclosure of each application is incorporated herein by reference.

### BACKGROUND

### 1. Field of the Disclosure

The present disclosure relates to a semiconductor device.

### 2. Description of the Related Art

Japanese Patent Application Publication No. 2011-199109 disclosed a semiconductor device which has a semiconductor substrate, an n-type drift region, a p-type body region, and a trench gate electrode.

### BRIEF DESCRIPTION OF THE DRAWINGS

FIG. 1 is a plan view which shows a semiconductor device according to a first embodiment.

FIG. 2 is a plan view which shows a structure of a first main surface of a chip shown in FIG. 1.

FIG. 3 is an enlarged view of a region III shown in FIG. 2.

FIG. 4 is an enlarged view of a region IV shown in FIG. 2.

FIG. 5 is a cross-sectional view taken along line V-V shown in FIG. 3.

FIG. 6 is a cross-sectional view taken along line VI-VI shown in FIG. 3.

FIG. 7 is a cross-sectional view taken along line VII-VII shown in FIG. 3.

FIG. 8 corresponds to FIG. 2 and is a plan view which shows a structure of a first main surface of a chip of a semiconductor device according to a second embodiment.

FIG. 9 is an enlarged view of a region IX shown in FIG. 8.

FIG. 10 is a cross-sectional view taken along line X-X shown in FIG. 9.

FIG. 11 is a cross-sectional view taken along line XI-XI shown in FIG. 9.

FIG. 12 is a cross-sectional view taken along line XII-XII shown in FIG. 9.

FIG. 13 is a cross-sectional view taken along line XIII-XIII shown in FIG. 9.

FIG. 14 corresponds to FIG. 2 and is a plan view which shows a structure of a first main surface of a chip of a semiconductor device according to a third embodiment.

FIG. 15 corresponds to FIG. 5 and is a cross-sectional view which shows a modification example of a second region which is applied to the first to third embodiments.

FIG. 16 corresponds to FIG. 3 and is a plan view which shows a first modification example of a dummy trench structure applied to the first to third embodiments.

FIG. 17 is a cross-sectional view taken along line XVII-XVII shown in FIG. 16.

FIG. 18 corresponds to FIG. 5 and is a cross-sectional view which shows a second modification example of the dummy trench structure applied to the first to third embodiments.

FIG. 19 corresponds to FIG. 3 and is a plan view which shows a modification example of a device region applied to the first to third embodiments.

### DETAILED DESCRIPTION OF THE PREFERRED EMBODIMENTS

Hereinafter, a detailed description of the embodiments shall be given. The attached drawings are not necessarily drawn precisely but are schematic views and are not necessarily matched in scale, etc. Of the attached drawings, hatching is applied to some of plan views for clarifying a structure. The same reference sign is given to a corresponding structure in the attached drawings and a redundant description shall be omitted or simplified. For a structure the description of which is omitted or simplified, a description thereof made before such omission or simplification is applied.

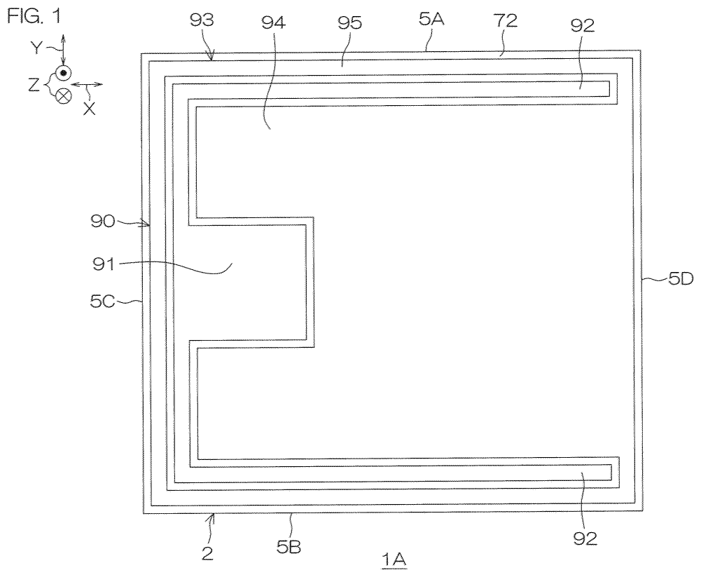

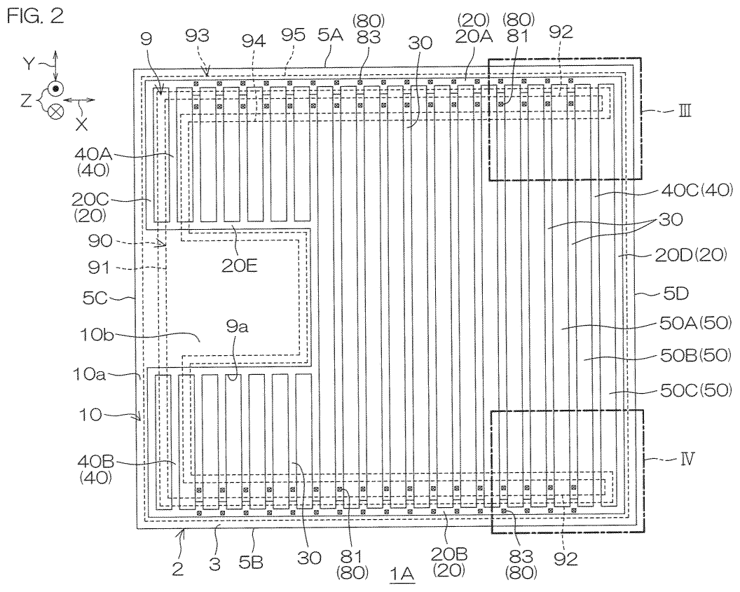

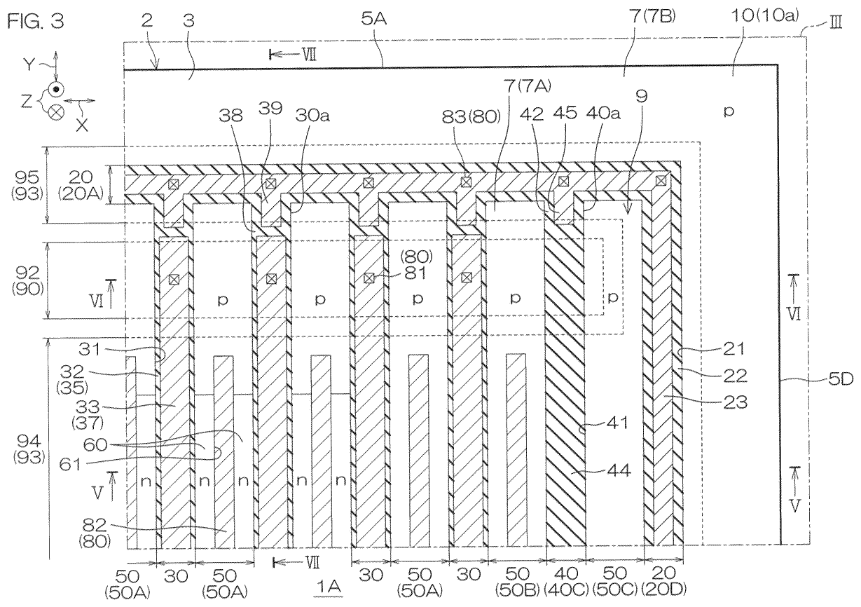

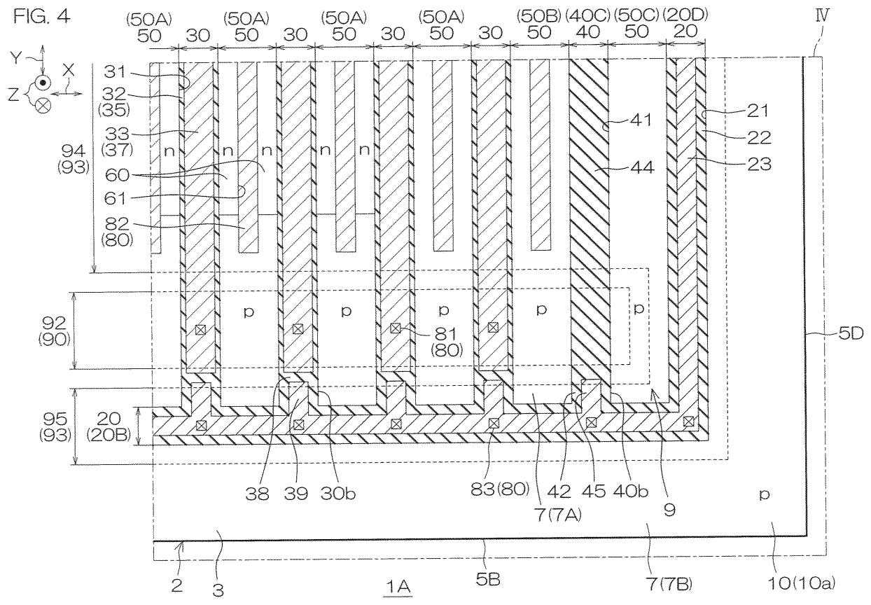

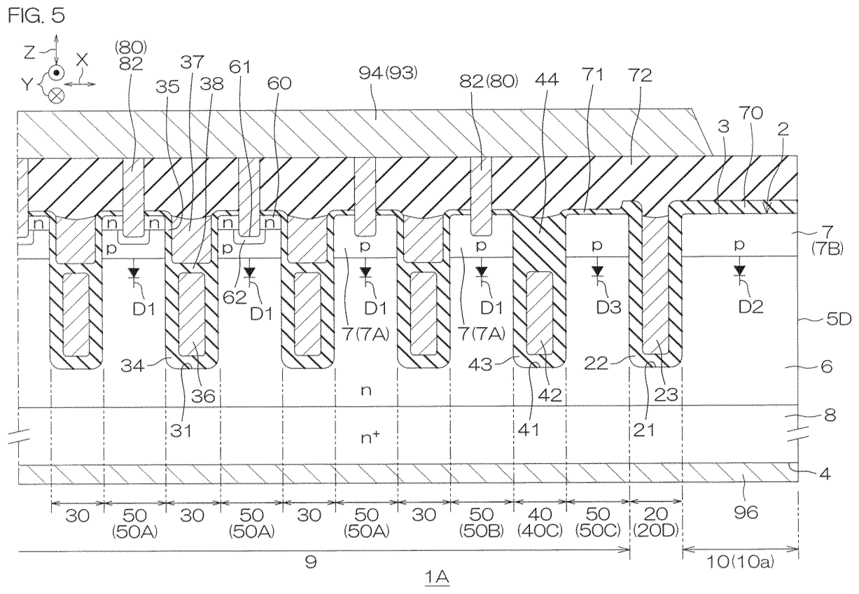

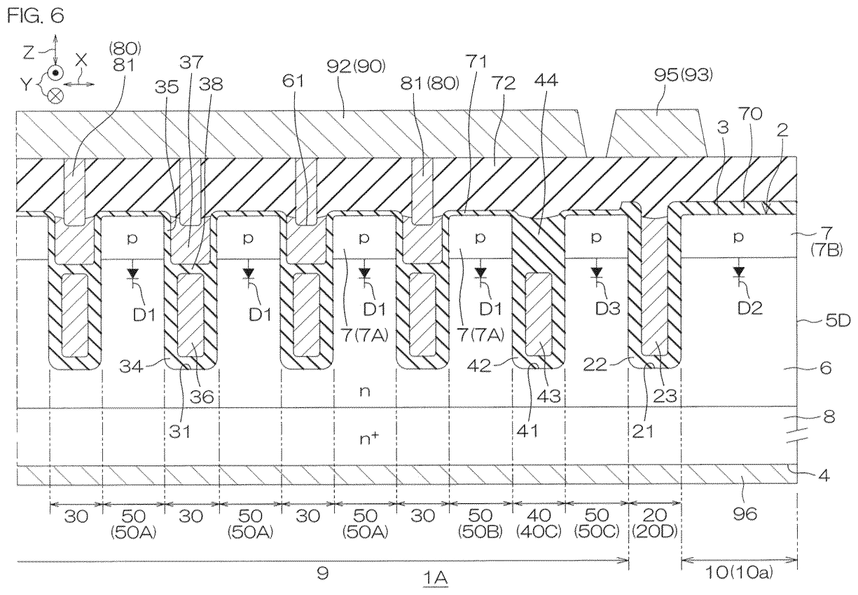

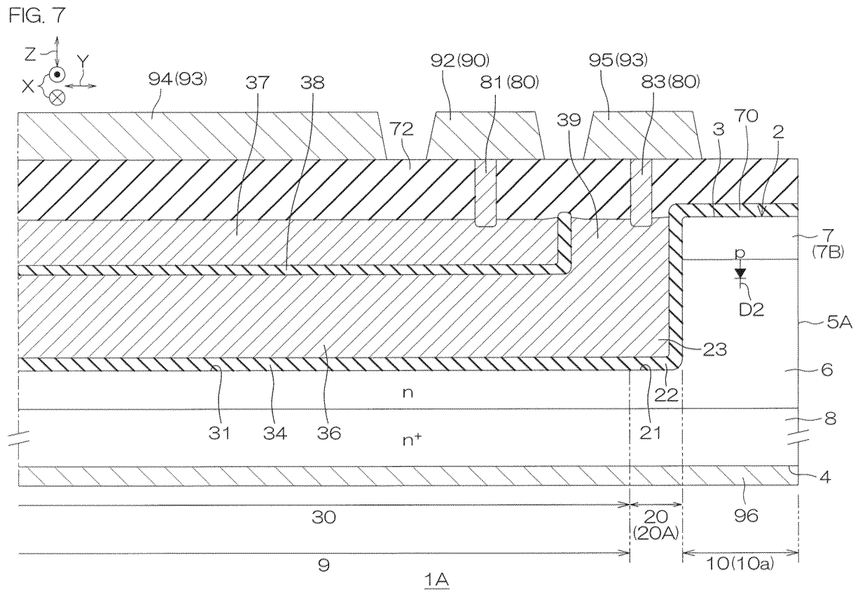

FIG. 1 is a plan view which shows a semiconductor device 1A according to a first embodiment. FIG. 2 is a plan view which shows a structure of a first main surface 3 of a chip 2 shown in FIG. 1. FIG. 3 is an enlarged view of a region III shown in FIG. 2. FIG. 4 is an enlarged view of a region IV shown in FIG. 2. FIG. 5 is a cross-sectional view taken along line V-V shown in FIG. 3. FIG. 6 is a cross-sectional view taken along line VI-VI shown in FIG. 3. FIG. 7 is a cross-sectional view taken along line VII-VII shown in FIG. 3.

With reference to FIG. 1 to FIG. 7, in this embodiment, the semiconductor device 1A is a switching device having a trench insulating gate type MISFET (Metal Insulator Semiconductor Field Effect Transistor) as an example of a field effect transistor.

The semiconductor device 1A includes the silicon-made chip 2 (semiconductor chip) which is formed in a rectangular parallelepiped shape. The chip 2 includes the first main surface 3 at one side, a second main surface 4 at the other side, and a first to fourth side surfaces 5A to 5D which connect the first main surface 3 and the second main surface 4. The first main surface 3 and the second main surface 4 are formed in quadrilateral shapes in a plan view as viewed from a normal direction Z thereto (hereinafter, simply referred to as “plan view”). The first side surface 5A and the second side surface 5B extend in a first direction X along the first main surface 3 and face each other (face opposite to each other) in a second direction Y that intersects (specifically, orthogonal to) the first direction X. The third side surface 5C and the fourth side surface 5D extend in the second direction Y and face each other in the first direction X.

The semiconductor device 1A includes an n-type (first conductivity type) first region 6 which is formed in a surface layer portion of the first main surface 3 of the chip 2. The first region 6 is formed inside the chip 2 at an interval from the second main surface 4 to the first main surface 3 side. The first region 6 may be referred to as a “drift region.” The first region 6 is formed in a layer shape extending along the first main surface 3 and exposed from at least one of the first to fourth side surfaces 5A to 5D.

In this embodiment, the first region 6 is formed in an entire area of the surface layer portion of the first main surface 3 and exposed from all of the first to fourth side surfaces 5A to 5D. The first region 6 may have a thickness of not less than 2 μm and not more than 30 μm (preferably not less than 5 μm and not more than 15 μm). In this embodiment, the first region 6 is formed by an n-type epitaxial layer (specifically, Si epitaxial layer).

The semiconductor device 1A includes a p-type (second conductivity type) second region 7 which is formed in a surface layer portion of the first region 6. The second region 7 is formed inside the first region 6 at an interval from a bottom portion of the first region 6 to the first main surface 3 side. The second region 7 may be referred to as a “body region.” The second region 7 is formed in a layer shape extending along the first main surface 3 and exposed from the first main surface 3 and at least one of the first to fourth side surfaces 5A to 5D.

In this embodiment, the second region 7 is formed in an entire area of the surface layer portion of the first region 6 and exposed from an entire area of the first main surface 3 and all of the first to fourth side surfaces 5A to 5D. The second region 7 has a p-type impurity concentration gradient which gradually decreases from the first main surface 3 toward the first region 6 side. The second region 7 does not have a portion which undergoes an abrupt change in p-type impurity concentration in a thickness direction with respect to a direction along the first main surface 3 (first direction X and second direction Y). The second region 7 has a bottom portion which extends flat along the first main surface 3 and does not have a portion which undergoes an abrupt change in thickness.

That is, the second region 7 has a uniform impurity concentration and a uniform thickness at the surface layer portion of the first region 6. The second region 7 may have a thickness of not less than 0.1 μm and not more than 3 μm (preferably, not less than 0.5 μm and not more than 1.5 μm). The second region 7 has a p-type impurity concentration higher than the first region 6 and replaces an n-type of the first region 6 with a p-type.

The semiconductor device 1A includes an n-type third region 8 which is formed in a surface layer portion of the second main surface 4 of the chip 2. The third region 8 has an n-type impurity concentration higher than the first region 6 and is electrically connected to the first region 6 inside the chip 2. The third region 8 may be referred to as a “drain region.” The third region 8 is formed in a layer shape extending along the second main surface 4 and exposed from the second main surface 4 and at least one of the first to fourth side surfaces 5A to 5D.

In this embodiment, the third region 8 is formed in an entire area of the surface layer portion of the second main surface 4 and exposed from the entire area of the second main surface 4 and all of the first to fourth side surfaces 5A to 5D. The third region 8 is thicker than the first region 6. The third region 8 may have a thickness of not less than 50 μm and not more than 400 μm (preferably, not less than 50 μm and not more than 150 μm). In this embodiment, the third region 8 is formed by an n-type semiconductor substrate (specifically, Si substrate).

The semiconductor device 1A includes at least one (one in this embodiment) device region 9 set at an internal portion of the first main surface 3 (inner region). The device region 9 is a region in which a MISFET is formed. The number of the device regions 9 and their arrangement are arbitrary and adjusted in accordance with a size of the first main surface 3 and electrical characteristics of the MISFET which are to be accomplished. The device region 9 is set at the internal portion of the first main surface 3 at an interval from a peripheral edge of the first main surface 3 in plan view. In this embodiment, the device region 9 is set to a polygonal shape having four sides parallel to the first to fourth side surfaces 5A to 5D in plan view. The device region 9 has a curved portion 9a which is concavely recessed toward the fourth side surface side in a side at the third side surface 5C side. In this embodiment, the curved portion 9a is recessed in a quadrilateral shape in plan view.

The semiconductor device 1A includes an outer region 10 which is set in a region outside the device region 9 in the first main surface 3. The outer region 10 is a region where MISFET is not formed and set at a peripheral edge portion of the first main surface 3. The outer region includes an annular region 10a and a pad region 10b. The annular region 10a is set to an annular (specifically, quadrilateral annular) shape extending along the peripheral edge of the first main surface 3 (first to fourth side surfaces 5A to 5D) in plan view and surrounds the device region 9. The pad region 10b is set in a region which is demarcated by the curved portion 9a of the device region 9 in plan view and protrudes toward the fourth side surface from a portion of the annular region 10a along a central portion of the third side surface 5C. In this embodiment, the pad region 10b is set to a quadrilateral shape in plan view.

The semiconductor device 1A includes a trench separation structure 20 which is formed in the first main surface 3. The trench separation structure 20 is formed in an annular shape which surrounds an interior of the second region 7 at an interval from the peripheral edge of the first main surface 3 in plan view. The trench separation structure 20 penetrates through the second region 7 in a cross-sectional view. The trench separation structure 20 demarcates the device region 9 at an inner side of the second region 7 and the outer region 10 at an outer side of the second region 7 in the first main surface 3.

In other words, the trench separation structure separates the second region 7 into a portion positioned inside the device region 9 and a portion positioned inside the outer region 10. The second region 7 inside the device region 9 may be referred to as a “first body region 7A” and the second region 7 inside the outer region 10 may be referred to as a “second body region 7B.” The trench separation structure 20 may have a width of not less than 0.1 μm and not more than 3 μm (preferably, not less than 0.5 μm and not more than 2 μm) with respect to a direction orthogonal to an extending direction. The plurality of trench separation structures 20 may have depths of not less than 1 μm and not more than 10 μm (preferably, not less than 1 μm and not more than 5 μm).

In this embodiment, the trench separation structure 20 is formed in a polygonal annular shape having four sides parallel to the first to fourth side surfaces 5A to 5D in plan view. Specifically, the trench separation structure 20 integrally includes a first to fourth trench separation structures 20A to 20D. The first trench separation structure 20A is positioned at the first side surface 5A side, the second trench separation structure 20B is positioned at the second side surface 5B side, the third trench separation structure 20C is positioned at the third side surface 5C side, and the fourth trench separation structure 20D is positioned at the fourth side surface 5D side.

A pair of first trench separation structure 20A and second trench separation structure 20B are separated in the second direction Y and extend in the first direction X in plan view. Where a line which crosses a central portion of the first main surface 3 in the first direction X is set, the first trench separation structure 20A is positioned at the first side surface 5A side with respect to the line, and the second trench separation structure 20B is positioned at the second side surface 5B side with respect to the line.

A pair of third trench separation structure 20C and fourth trench separation structure 20D are separated in the first direction X and extend in the second direction Y. Where a line which crosses the central portion of the first main surface 3 in the second direction Y is set, the third trench separation structure 20C is positioned at the third side surface 5C side with respect to the line, and the fourth trench separation structure 20D is positioned at the fourth side surface 5D side with respect to the line. The trench separation structure 20 has a trench curved portion 20E which is concavely recessed toward the fourth side surface 5D side in the third trench separation structure 20C. In this embodiment, the trench curved portion 20E is recessed in a quadrilateral shape in plan view and demarcates the pad region 10b of the outer region 10 (curved portion 9a of device region 9).

The trench separation structure 20 includes a separation trench 21, a separation insulating film 22, and a separation electrode 23. The trench separation structure has a single electrode structure which includes the single separation electrode 23. The separation trench 21 is formed in the first main surface 3 and demarcates an inner wall (bottom wall and side wall) of the trench separation structure 20. The separation trench 21 penetrates through the second region 7 and is at an interval from the bottom portion of the first region 6 to the first main surface 3 side.

The separation insulating film 22 covers a wall surface of the separation trench 21. The separation insulating film 22 is formed as a relatively thick field insulating film. The separation insulating film 22 may include a silicon oxide film. The separation electrode 23 is embedded in the separation trench 21 as an integrated member across the separation insulating film 22. The separation electrode 23 may include conductive polysilicon. A source potential is to be applied to the separation electrode 23. The source potential may be a reference potential which is served as a reference of circuit operation or a ground potential.

The semiconductor device 1A includes a plurality of trench gate structures 30 which are formed in the first main surface 3 of the device region 9. In the following description, the “first side surface 5A side” is referred to as “one side” and the “second side surface 5B side” is referred to as “the other side.” The plurality of trench gate structures 30 are arranged at an interval in the first direction X and each is formed in a band shape extending in the second direction Y. That is, the plurality of trench gate structures 30 are formed in a stripe shape extending in the second direction Y in plan view. The trench separation structure 20 penetrates through the second region 7 in a cross-sectional view.

The plurality of trench gate structures 30 include at least one trench gate structure 30 (a plurality in this embodiment) which faces the pad region 10b in the first direction X in plan view. The plurality of trench gate structures 30 include at least one trench gate structure 30 (a plurality in this embodiment) which faces the pad region 10b in the second direction Y in plan view. The trench gate structure 30 which faces the pad region 10b in the second direction Y is shorter than the trench gate structure 30 which faces the pad region 10b in the first direction X.

The plurality of trench gate structures 30 each have a first end portion 30a at one side and a second end portion 30b at the other side with regard to the second direction Y. In this embodiment, both end portions 30a, of the plurality of trench gate structures 30 are respectively connected to the pair of trench separation structures 20 (first trench separation structure 20A and second trench separation structure 20B) extending in the first direction X.

An interval between the plurality of trench gate structures 30 is preferably set in such a range that a depletion layer covers a bottom wall of the trench separation structure 20 and bottom walls of the plurality of trench gate structures 30. The plurality of trench gate structures 30 may be arrayed at an interval of not less than 0.1 μm and not more than 2 μm (preferably, not less than 0.5 μm and not more than 1.5 μm). The plurality of trench gate structures 30 are preferably arrayed at substantially equal intervals in the first direction X.

The plurality of trench gate structures 30 may each have a width of not less than 0.1 μm and not more than 3 μm (preferably, not less than 0.5 μm and not more than 2 μm) with regard to the first direction X. It is preferable that the plurality of trench gate structures 30 are substantially equal in width to the trench separation structure 20. The plurality of trench gate structures 30 may have a depth of not less than 1 μm and not more than 10 μm (preferably, not less than 1 μm and not more than 5 μm). It is preferable that the plurality of trench gate structures 30 are substantially equal in depth to the trench separation structure 20.

Hereinafter, a description of an inner structure of one trench gate structure 30 shall be given. The trench gate structure 30 includes a gate trench 31, a gate insulating film 32, and a gate electrode 33. The gate trench 31 is formed in the first main surface 3 and demarcates wall surface (side wall and bottom wall) of the trench gate structure 30. The gate trench 31 penetrates through the second region 7 and is at an interval from the bottom portion of the first region 6 to the first main surface 3 side. The gate trench 31 is substantially equal in width and depth to the separation trench 21. The gate trench 31 has both end portions 30a, 30b which are in communication with the trench separation structure 20 (separation trench 21) with regard to the second direction Y.

The gate insulating film 32 covers an opening-side wall surface and a bottom-side wall surface of the gate trench 31. The opening-side wall surface is a wall surface positioned at the opening side of the gate trench 31 with respect to a bottom portion of the second region 7. The bottom-side wall surface is a wall surface positioned at a bottom wall side of the gate trench 31 with respect to the bottom portion of the second region 7. The gate insulating film 32 is connected to the separation insulating film 22 at a communicatively connecting portion of the separation trench 21 and the gate trench 31. In this embodiment, the gate insulating film 32 includes a lower insulating film 34 and an upper insulating film 35 different in thickness from the lower insulating film 34.

The lower insulating film 34 covers the bottom-side wall surface of the gate trench 31. The lower insulating film 34 is in contact with the first region 6 which is exposed from the wall surface of the gate trench 31. The lower insulating film 34 covers the opening-side wall surface and the bottom-side wall surface of the gate trench 31 at the both end portions 30a, 30b of the gate trench 31 with regard to the second direction Y and is connected to the separation insulating film 22 of the trench separation structure 20. As with the separation insulating film 22, the lower insulating film 34 is formed as a relatively thick field insulating film. The lower insulating film 34 may include a silicon oxide film.

The upper insulating film 35 covers the opening-side wall surface of the gate trench 31. The upper insulating film 35 has a portion which covers the first region 6 and a portion which covers the second region 7. The area covered by the upper insulating film 35 with respect to the second region 7 is larger than the area covered by the upper insulating film 35 with respect to the first region 6. The upper insulating film 35 is formed as a gate insulating film which is thinner than the lower insulating film 34. The upper insulating film 35 may include a silicon oxide film.

The gate electrode 33 is embedded in the gate trench 31 across the gate insulating film 32. Specifically, the gate electrode 33 has a multi-electrode structure which includes a lower electrode 36, an upper electrode 37, and an intermediate insulating film 38. The lower electrode 36 is embedded at the bottom wall side of the gate trench 31 across the gate insulating film 32 (specifically, lower insulating film 34). The lower electrode 36 faces the first region 6 across the lower insulating film 34. The lower electrode 36 is formed in a band shape extending in the second direction Y in plan view and is formed in a column shape extending in the normal direction Z in a cross-sectional view.

The lower electrode 36 is connected to the separation electrode 23 at a communicating portion of the separation trench 21 and the gate trench 31. Thereby, the lower electrode 36 is formed as a field electrode to which a source potential is to be applied. A connecting portion of the separation electrode 23 and the lower electrode 36 may be regarded as a part of the lower electrode 36 or may be regarded as a part of the separation electrode 23. The lower electrode 36 may include conductive polysilicon.

The lower electrode 36 includes a plurality of lead-out portions 39 which are led out from the bottom wall side of the gate trench 31 to the opening side thereof. The plurality of lead-out portions 39 include the lead-out portion 39 at one side (first side surface 5A side) and the lead-out portion 39 at the other side (second side surface 5B side) which is separated from the lead-out portion 39 at one side in the second direction Y. In this embodiment, the plurality of lead-out portions 39 are each formed at the both end portions 30a, 30b of the gate trench 31 and led out to the opening side of the gate trench 31 across the lower insulating film 34.

The plurality of lead-out portions 39 extend in the second direction Y in plan view and are connected to the separation electrode 23 at the communicating portion of the separation trench 21 and the gate trench 31. The plurality of lead-out portions 39 demarcate a recess with the wall surface of the gate trench 31 at the opening side of the gate trench 31. The recess is demarcated as a band shape extending in the second direction Y in plan view.

The upper electrode 37 is embedded at the opening side inside the gate trench 31 across the gate insulating film 32 (specifically, upper insulating film 35). Specifically, the upper electrode 37 is embedded in the recess between the plurality of lead-out portions 39 at the opening side of the gate trench 31. The upper electrode 37 faces the first region 6 and the second region 7 across the upper insulating film 35. The upper electrode 37 is formed in a band shape extending in the second direction Y in plan view. The upper electrode 37 has a thickness less than a thickness of the lower electrode 36 with respect to the normal direction Z. The upper electrode 37 has an upper end portion positioned at the bottom wall side of the gate trench 31 with respect to the first main surface 3. The upper electrode 37 may include conductive polysilicon. A gate potential is to be applied to the upper electrode 37.

The intermediate insulating film 38 is interposed between the lower electrode 36 and the upper electrode 37 inside the gate trench 31 and electrically insulates the lower electrode 36 and the upper electrode 37. The intermediate insulating film 38 continues to the gate insulating film 32 (lower insulating film 34 and upper insulating film 35) inside the gate trench 31. The intermediate insulating film 38 is preferably thicker than the upper insulating film 35. The intermediate insulating film 38 may include a silicon oxide film. As described above, the trench gate structure 30 has an inner structure different from the trench separation structure 20.

The semiconductor device 1A includes, in the device region 9, at least one dummy trench structure 40 (three in this embodiment) which is formed in the first main surface 3. The three dummy trench structures 40 include a first dummy trench structure 40A, a second dummy trench structure 40B, and a third dummy trench structure 40C. The first to third dummy trench structures 40A to 40C are each interposed in a region between the trench separation structure 20 and the trench gate structure 30 at a peripheral edge portion of the device region 9.

The first dummy trench structure 40A is arranged in a region between the third trench separation structure and the trench gate structure 30 at one side (third side surface 5C side) in the first direction X and at one side (first side surface 5A side) in the second direction Y. The first dummy trench structure 40A faces the pad region 10b in the second direction Y across the trench separation structure 20.

The second dummy trench structure 40B is arranged in a region between the third trench separation structure 20C and the trench gate structure 30 at one side (third side surface 5C side) in the first direction X and at the other side (second side surface 5B side) in the second direction Y. The second dummy trench structure 40B faces the pad region 10b across the trench separation structure 20 in the second direction Y. Further, the second dummy trench structure 40B faces the first dummy trench structure 40A across the pad region 10b in the second direction Y.

The third dummy trench structure 40C is arranged in a region between the fourth trench separation structure 20D and the trench gate structure 30 at the other side (fourth side surface 5D side) in the first direction X. The third dummy trench structure 40C faces the pad region 10b across the plurality of trench gate structures 30 in the first direction X. Further, the third dummy trench structure 40C faces the first and second dummy trench structures 40A to 40B across the plurality of trench gate structures 30 in the first direction X. The third dummy trench structure 40C is longer than the first and second dummy trench structures 40A and 40B.

The plurality of dummy trench structures 40 are formed at an interval from the trench separation structure 20 and the trench gate structure 30 in the first direction X and are formed in a band shape extending in the second direction Y. An entire area of each dummy trench structure faces the trench separation structure 20 and the trench gate structure 30 in the first direction X. The plurality of dummy trench structures 40 penetrate through the second region 7 in a cross-sectional view.

The plurality of dummy trench structures 40 each have a first end portion 40a at one side and a second end portion 40b at the other side with regard to the second direction Y. In this embodiment, both end portions 40a, 40b of the plurality of dummy trench structures 40 are respectively connected to the pair of trench separation structures 20 (first trench separation structure 20A and second trench separation structure 20B) extending in the first direction X.

In this embodiment, the plurality of dummy trench structures 40 are electrically connected to the trench separation structure 20 and electrically separated from the plurality of trench gate structures 30. Specifically, the plurality of dummy trench structures 40 are electrically connected to the separation electrode 23 of the trench separation structure 20 and electrically separated from the upper electrodes 37 of the plurality of trench gate structures 30. Therefore, the plurality of dummy trench structures 40 do not function as the trench gate structure 30.

The dummy trench structures 40 is each formed at a first interval from the adjacent trench separation structure 20 and is formed at a second interval from the adjacent trench gate structure 30. The first interval and the second interval are preferably set in such a range that a depletion layer covers a bottom wall of the trench separation structure 20, bottom walls of the plurality of trench gate structures 30, and bottom walls of the plurality of dummy trench structures 40. The first interval and the second interval may be not less than 0.1 μm and not more than 2 μm (preferably, not less than 0.5 μm and not more than 1.5 μm). It is preferable that the first interval and the second interval are substantially equal to an interval between the plurality of trench gate structures 30. It is preferable that the second interval is substantially equal to the first interval.

The dummy trench structures 40 may each have a width of not less than 0.1 μm and not more than 3 μm (preferably, not less than 0.5 μm and not more than 2 μm) with regard to the first direction X. It is preferable that a width of each dummy trench structure 40 is substantially equal to a width of the trench separation structure 20 (trench gate structure 30). The dummy trench structures 40 may each have a depth of not less than 1 μm and not more than 10 μm (preferably, not less than 1 μm and not more than 5 μm). It is preferable that the dummy trench structures are each substantially equal in depth to the trench separation structure 20 (trench gate structure 30).

The plurality of dummy trench structures 40 each have an inner structure different from the trench separation structure 20. The plurality of dummy trench structures 40 each have an inner structure different from the trench gate structure 30. Hereinafter, a description of an inner structure of one dummy trench structure 40 shall be given. The dummy trench structure 40 has a single electrode structure which includes a dummy trench 41, a dummy insulating film 42, a dummy electrode 43, and an embedded insulator 44. The embedded insulator 44 may be referred to as a “field insulator.”

The dummy trench 41 is formed in the first main surface 3 and demarcates wall surface (side wall and bottom wall) of the dummy trench structure 40. The dummy trench 41 penetrates through the second region 7 and is at an interval from the bottom portion of the first region 6 to the first main surface 3 side. The dummy trench 41 is substantially equal in width and depth to the separation trench 21. The dummy trench 41 has both end portions 40a, which are in communication with the trench separation structure 20 (separation trench 21) with regard to the second direction Y.

The dummy insulating film 42 covers a bottom-side wall surface of the dummy trench 41. The bottom-side wall surface is a wall surface which is positioned at the bottom wall side of the dummy trench 41 with respect to the bottom portion of the second region 7. The dummy insulating film 42 is in contact with the first region 6 exposed from the wall surface of the dummy trench 41. The dummy insulating film 42 covers the opening-side wall surface and the bottom-side wall surface of the dummy trench 41 at the both end portions 40a, 40b of the dummy trench 41 with regard to the second direction Y and is connected to the separation insulating film 22 of the trench separation structure 20. The dummy insulating film 42 is thicker than the upper insulating film 35 of the trench gate structure 30. The dummy insulating film 42 is formed as a relatively thick field insulating film, as with the separation insulating film 22 (lower insulating film 34). The dummy insulating film 42 may include a silicon oxide film.

The dummy electrode 43 is embedded at the bottom wall side of the dummy trench 41 across the dummy insulating film 42. The dummy electrode 43 faces the first region 6 across the dummy insulating film 42. The dummy electrode 43 is formed in a band shape extending in the second direction Y in plan view and is formed in a column shape extending in the normal direction Z in a cross-sectional view. The dummy electrode 43 faces the separation electrode 23 of the trench separation structure 20 and the lower electrode 36 of the trench gate structure 30 in the first direction X. The dummy electrode 43 preferably does not face the upper electrode 37 of the trench gate structure 30 in the first direction X.

The dummy electrode 43 is connected to the separation electrode 23 at a communicating portion of the separation trench 21 and the dummy trench 41. The dummy electrode 43 is electrically insulated from the upper electrode 37 by the intermediate insulating film 38 of the trench gate structure 30. Thereby, the dummy electrode 43 is formed as a field electrode to which a source potential is to be applied. The connecting portion of the separation electrode 23 and the dummy electrode 43 may be regarded as a part of the dummy electrode 43 or may be regarded as a part of the separation electrode 23. The dummy electrode 43 may include conductive polysilicon.

The dummy electrode 43 includes a plurality of dummy lead-out portions 45 which are led out from the bottom wall side of the dummy trench 41 to the opening side thereof. The plurality of dummy lead-out portions 45 include the dummy lead-out portion 45 at one side (first side surface side) and the dummy lead-out portion 45 at the other side (second side surface 5B side) which is separated from the dummy lead-out portion 45 at one side in the second direction Y. In this embodiment, the plurality of dummy lead-out portions 45 are each formed at the both end portions 40a, 40b of the dummy trench 41 and led out to the opening side of the dummy trench 41 across the dummy insulating film 42.

The plurality of dummy lead-out portions 45 extend in the second direction Y in plan view and are connected to the separation electrode 23 at a communicating portion of the separation trench 21 and the dummy trench 41. The plurality of dummy lead-out portions 45 face the separation electrode 23 of the trench separation structure and the plurality of lead-out portions 39 of the trench gate structure 30 in the first direction X. The plurality of dummy lead-out portions 45 demarcate a recess with the wall surface of the dummy trench 41 at the opening side of the dummy trench 41. The recess is demarcated as a band shape extending in the second direction Y in plan view.

The embedded insulator 44 is embedded at the opening side inside the dummy trench 41 and seals the dummy electrode 43 inside the dummy trench 41. Specifically, the embedded insulator 44 is embedded in the recess which is demarcated by the side wall of the dummy trench 41 and the dummy electrode 43 (the plurality of dummy lead-out portions 45) inside the dummy trench 41. The embedded insulator 44 faces the first region 6 and the second region 7 across the upper insulating film 35.

The embedded insulator 44 preferably covers an entire area of the dummy electrode 43 inside the recess. The embedded insulator 44 faces the separation electrode 23 of the trench separation structure 20 and the upper electrode 37 of the trench gate structure 30 in the first direction X. The embedded insulator 44 preferably does not face the lower electrode 36 of the trench gate structure 30 in the first direction X. The embedded insulator 44 may include silicon oxide. The embedded insulator 44 is thicker than the separation insulating film 22 (lower insulating film 34).

As described above, the dummy trench structure has an inner structure different from the trench separation structure 20 in that the dummy trench structure includes the embedded insulator 44 which covers the dummy electrode 43 inside the dummy trench 41. Further, the dummy trench structure 40 has an inner structure different from the trench gate structure 30 in that the dummy trench structure 40 does not include an electrode which faces the dummy electrode 43 across the embedded insulator 44 inside the dummy trench 41. The dummy trench structure 40 relaxes a stress which is generated between the trench separation structure 20 and the trench gate structure 30, each of which has an inner structure different from each other and suppresses fluctuations in electrical characteristics resulting from the stress.

The semiconductor device 1A includes a plurality of mesa portions 50 which are demarcated in the device region 9. The plurality of mesa portions 50 are each demarcated by the trench separation structure 20, the plurality of trench gate structures 30, and the plurality of dummy trench structures 40. The plurality of mesa portions 50 are each constituted of a part of the chip 2 and each include the first region 6 and the second region 7. The plurality of mesa portions 50 are demarcated at an interval in the first direction X and each is formed in a band shape extending in the second direction Y. That is, the plurality of mesa portions 50 are formed in a stripe shape extending in the second direction Y. Further, the plurality of mesa portions 50 each include the first region 6 and the second region 7 extending in a band shape along the second direction Y.

The plurality of mesa portions 50 include a plurality of first mesa portions 50A, a plurality of second mesa portions 50B, and a plurality of third mesa portions Each of the first mesa portions 50A is demarcated in a region between a pair of trench gate structures 30 which are mutually adjacent in the first direction X. Specifically, each of the first mesa portions 50A is demarcated by the pair of trench gate structures 30 which are mutually adjacent in the first direction X in a region between the pair of trench separation structures 20 extending in the first direction X. That is, each of the first mesa portions 50A is demarcated by an annular trench structure which integrally includes the pair of trench separation structures 20 and the pair of trench gate structures 30.

Each of the second mesa portions 50B is demarcated in a region between the trench gate structure 30 and the dummy trench structure 40 mutually adjacent in the first direction X. Specifically, each of the second mesa portions 50B is demarcated in a region between the pair of trench separation structures 20 extending in the first direction X by the trench gate structure 30 and the dummy trench structure 40 mutually adjacent in the first direction X. That is, each of the second mesa portions 50B is demarcated by an annular trench structure which integrally includes the pair of trench separation structures 20, the trench gate structure 30, and the dummy trench structure 40.

Each of the third mesa portions 50C is demarcated in a region between the trench separation structure 20 and the dummy trench structure 40 mutually adjacent in the first direction X. Specifically, each of the third mesa portions is demarcated in a region between the pair of trench separation structures 20 extending in the first direction X by the trench separation structure 20 and the dummy trench structure 40 mutually adjacent in the first direction X. That is, each of the third mesa portions 50C is demarcated by an annular trench structure which integrally includes the pair of trench separation structures 20 extending in the first direction X, the trench separation structure 20 extending in the second direction Y, and the dummy trench structure 40.

The semiconductor device 1A includes at least one inner diode D1 (a plurality in this embodiment) formed in the device region 9. The plurality of inner diodes D1 each have the first region 6 and the second region 7 (first body region 7A) that are positioned in the device region 9. Specifically, the plurality of inner diodes D1 are each formed inside the plurality of first mesa portions 50A and the plurality of second mesa portions 50B and also each include the first region 6 and the second region 7 which form a pn junction portion. That is, the plurality of inner diodes D1 each include the first region 6 as a cathode and the second region 7 as an anode.

The plurality of inner diodes D1 are arrayed at an interval in the first direction X in plan view and each is formed in a band shape extending in the second direction Y. The cathode (first region 6) of the inner diode D1 is electrically connected to the third region 8. The anode (second region 7) of the inner diode D1 is electrically connected to the separation electrode 23 of the trench separation structure 20, the lower electrode 36 of the trench gate structure 30, and the dummy electrode 43 of the dummy trench structure 40. That is, the inner diode D1 is electrically connected between a source and a drain and functions as a body diode of the MISFET.

The semiconductor device 1A includes at least one outer diode D2 (one in this embodiment) which is positioned in the outer region 10. In this embodiment, the semiconductor device 1A does not include the trench gate structure 30 which penetrates through the outer diode D2 in the outer region 10. That is, only the outer diode D2 is formed in the outer region 10. The outer diode D2 has the first region 6 and the second region 7 (second body region 7B) that are positioned in the outer region 10. Specifically, the outer diode D2 includes the first region 6 and the second region 7 which form a pn junction portion inside the outer region 10. That is, the plurality of outer diodes D2 include the first region 6 as a cathode and the second region 7 as an anode.

The outer diode D2 may be exposed from at least one of the first to fourth side surfaces 5A to 5D. In this embodiment, the outer diode D2 is formed in an entire area of a region between the peripheral edge of the first main surface 3 and the trench separation structure 20 and exposed from all of the first to fourth side surfaces 5A to 5D. That is, the outer diode D2 is formed in an entire area of the outer region 10 (annular region 10a and pad region 10b) in plan view and surrounds the device region 9.

The outer diode D2 is electrically separated from the plurality of trench gate structures 30, the plurality of dummy trench structures 40, and the plurality of inner diodes D1 by the trench separation structure 20. Specifically, the outer diode D2 is electrically separated from the separation electrode 23 of the trench separation structure 20, the lower electrode 36 and the upper electrode 37 of the trench gate structure 30, as well as the dummy electrode 43 of the dummy trench structure 40.

In this embodiment, the cathode of the outer diode D2 is electrically connected to the cathode of the inner diode D1 via the first region 6, and the anode of the outer diode D2 is electrically opened. Therefore, the outer diode D2 is constituted of a floating diode which is formed in an electrically floating state between a source and a drain and does not function as a body diode of the MISFET.

The semiconductor device 1A includes at least one intermediate diode D3 (three in this embodiment) which is formed in a region of the device region 9 different from the inner diode D1 (peripheral edge portion of device region 9). Specifically, the plurality of intermediate diodes D3 are each formed inside the plurality of third mesa portions 50C and each include the first region 6 and the second region 7 (first body region 7A) which form a pn junction portion. That is, the plurality of intermediate diodes D3 each include the first region 6 as a cathode and the second region 7 as an anode.

The plurality of intermediate diodes D3 are each formed in a band shape extending in the second direction Y. The plurality of intermediate diodes D3 each face the inner diode D1 across the corresponding dummy trench structure 40 and also each face the outer diode D2 across the trench separation structure 20. The plurality of intermediate diodes D3 sandwich the plurality of inner diodes D1 from both sides in the first direction X in plan view.

The plurality of intermediate diodes D3 are electrically separated from the plurality of trench gate structures 30, the plurality of inner diodes D1, and the outer diode D2 by the trench separation structure 20 and the plurality of dummy trench structures 40. Specifically, the plurality of intermediate diodes D3 are electrically separated from the separation electrode 23 of the trench separation structure 20, the lower electrode 36 and the upper electrode 37 of the trench gate structure 30, as well as the dummy electrode 43 of the dummy trench structure 40.

In this embodiment, the cathode of the intermediate diode D3 is electrically connected to the cathode of the inner diode D1 and the cathode of the outer diode D2 via the first region 6, and the anode of the intermediate diode D3 is electrically opened. Therefore, as with the outer diode D2, the plurality of intermediate diodes D3 are each constituted of a floating diode formed in an electrically floating state between a source and a drain and do not function as a body diode of the MISFET.

The semiconductor device 1A includes a plurality of source regions 60 (impurity regions) which are formed in a surface layer portion of the second region 7 so as to be in contact with the plurality of trench gate structures 30 in the device region 9. The plurality of source regions 60 each have an n-type impurity concentration higher than the first region 6 and are each formed at an interval from the bottom portion of the second region 7 to the first main surface 3 side.

Specifically, the plurality of source regions 60 are each formed in a region between a plurality of trench gate structures 30 which are mutually adjacent. In this embodiment, the plurality of source regions 60 are not formed in a region between the trench gate structure 30 and the dummy trench structure 40 which are mutually adjacent. Further, in this embodiment, the plurality of source regions are not formed in a region between the trench separation structure 20 and the dummy trench structure 40. That is, the plurality of source regions 60 are formed only at the plurality of first mesa portions 50A but not formed at the second and third mesa portions 50B and 50C. Further, in this embodiment, the source region 60 is not formed at the first mesa portion 50A which is the outermost one among the plurality of first mesa portions 50A and is mutually adjacent to the second mesa portion 50B.

The plurality of source regions 60 are formed at an interval from the trench separation structure 20. Specifically, the plurality of source regions 60 are each formed at an interval in the second direction Y from the pair of trench separation structures 20 extending in the first direction X. That is, the plurality of source regions are connected to the plurality of trench gate structures in the first direction X but not connected to the plurality of trench separation structures 20 in the second direction Y.

The plurality of source regions 60 are each formed in a band shape extending in the second direction Y. With respect to the corresponding trench gate structure 30, the plurality of source regions 60 each face the gate electrode 33 across the gate insulating film 32. Specifically, the plurality of source regions 60 face the upper electrode 37 across the upper insulating film 35 but do not face the lower electrode 36. The plurality of source regions 60 are each formed at a further inner side than the plurality of lead-out portions 39 of the trench gate structure 30 in plan view.

Specifically, the plurality of source regions 60 are each formed in a region between the plurality of lead-out portions 39 in plan view and do not face the plurality of lead-out portions 39 in the first direction X. An entire area of the plurality of source regions 60 faces the upper electrode 37 of one or the plurality of trench gate structures 30 which are adjacent. The plurality of source regions 60 each form a channel of the MISFET with the first region 6 inside the second region 7. That is, the plurality of channels are formed at the plurality of first mesa portions 50A (in this embodiment, those excluding the outermost first mesa portion 50A) but not formed at the second and third mesa portions 50B and 50C. The plurality of channels are each controlled by the plurality of trench gate structures 30.

The semiconductor device 1A includes a plurality of contact holes 61 which are each formed in the first main surface 3 so as to penetrate through the plurality of source regions 60. Specifically, the plurality of contact holes 61 are formed in a region between the plurality of trench gate structures 30 which are mutually adjacent at an interval from the plurality of trench gate structures 30. Further, the plurality of contact holes 61 are formed in a region between the trench gate structure 30 and the dummy trench structure 40 which are mutually adjacent at an interval from the trench gate structure 30 and the dummy trench structure 40. The plurality of contact holes 61 are not formed in a region between the trench separation structure 20 and the dummy trench structure 40 which are mutually adjacent. That is, the plurality of contact holes 61 are formed at the first and second mesa portions 50A and (including the outermost first mesa portion 50A) but not formed at the third mesa portion 50C.

The plurality of contact holes 61 are formed at an interval from the plurality of trench gate structures 30 and the plurality of dummy trench structures 40 in the first direction X and are formed at an interval from the plurality of trench separation structures 20 in the second direction Y. The plurality of contact holes 61 are each formed in a band shape extending in the second direction Y. The plurality of contact hole 61 may cross an end portion of a source region 60 corresponding in the second direction Y in plan view. The plurality of contact holes 61 are each formed at a further inner side than the plurality of lead-out portions 39 of the trench gate structure 30 in plan view.

Specifically, the plurality of contact holes 61 are each formed in a region between the plurality of lead-out portions 39 in plan view and do not face the plurality of lead-out portions 39 in the first direction X. An entire area of the plurality of contact holes 61 faces the upper electrodes 37 of the plurality of trench gate structures 30 in the first direction X in plan view.

The semiconductor device 1A includes a plurality of p-type contact regions 62 which are each formed in a region along the plurality of contact holes 61 at the surface layer portion of the second region 7. The plurality of contact regions 62 each have a p-type impurity concentration higher than the second region 7 and each cover a bottom wall of the corresponding contact hole 61 at an interval from the bottom portion of the second region 7. The plurality of contact regions 62 may be formed in a band shape extending along a bottom wall of the corresponding contact hole 61 in plan view. The plurality of contact regions 62 are formed at an interval from the plurality of trench gate structures 30 in the first direction X and are formed at an interval from the plurality of trench separation structures 20 in the second direction Y. The plurality of contact regions 62 may cover a side wall of the corresponding contact hole 61.

The semiconductor device 1A includes a field insulating film 70 which covers a periphery of the trench separation structure 20 on the first main surface 3. In this embodiment, the field insulating film 70 includes a silicon oxide film. Specifically, the field insulating film 70 is formed along an inner wall of the trench separation structure 20 in the device region 9 and is formed along an outer wall of the trench separation structure 20 in the outer region 10.

The field insulating film 70 covers a region between the trench separation structure 20 and the dummy trench structure 40 (that is, a region including the third mesa portion 50C) in the device region 9 and exposes the plurality of trench gate structures 30 and the plurality of dummy trench structures 40. That is, the field insulating film 70 exposes the inner diode D1 and the intermediate diode D3. The field insulating film 70 continues to the separation insulating film 22 which is exposed from the inner wall side of the separation trench 21 so as to expose the separation electrode 23.

The field insulating film 70 covers a region between a peripheral edge of the first main surface 3 (first to fourth side surfaces 5A to 5D) and the trench separation structure 20 in the outer region 10. That is, the field insulating film 70 covers the outer diode D2. In this embodiment, the field insulating film 70 covers an entire area of the outer region 10 and continues to the peripheral edge (first to fourth side surface 5A to 5D) of the first main surface 3. That is, in this embodiment, the field insulating film 70 covers an entire area of the outer diode D2.

The field insulating film 70 continues to the separation insulating film 22 which is exposed from the outer wall side of the separation trench 21 so as to expose the separation electrode 23. As a matter of course, the field insulating film 70 may cover the peripheral edge portion of the first main surface 3 at an interval inward from the peripheral edge of the first main surface 3 (first to fourth side surfaces 5A to 5D). That is, the field insulating film 70 may partially cover the outer diode D2.

The semiconductor device 1A includes a main surface insulating film 71 which selectively covers the first main surface 3. The main surface insulating film 71 is an insulating film thinner than the field insulating film and covers a region outside the field insulating film 70 on the first main surface 3. In this embodiment, the main surface insulating film 71 includes a silicon oxide film. Specifically, the main surface insulating film 71 covers a region outside the plurality of trench gate structures 30, the plurality of dummy trench structures 40, and the field insulating film 70 in the first main surface 3 and continues to the upper insulating film 35, the dummy insulating film 42, and the field insulating film 70.

That is, the main surface insulating film 71 covers the plurality of mesa portions 50 (first to third mesa portions 50A to 50C). The main surface insulating film 71 also covers the plurality of inner diodes D1 and the plurality of intermediate diodes D3. The main surface insulating film 71 is thinner than the separation insulating film 22 (lower insulating film 34). A thickness of the main surface insulating film 71 may be substantially equal to a thickness of the upper insulating film 35.

Where the field insulating film 70 is formed at an interval from the peripheral edge of the first main surface 3 (first to fourth side surfaces 5A to 5D), the main surface insulating film 71 may cover a portion which is exposed from the field insulating film 70 at the peripheral edge portion of the first main surface 3. In this case, the outer diode D2 is covered by the field insulating film and the main surface insulating film 71. The main surface insulating film 71 may continue to the peripheral edge of the first main surface 3 (first to fourth side surfaces 5A to 5D).

The semiconductor device 1A includes an interlayer insulating film 72 which covers the first main surface 3. The interlayer insulating film 72 may have a laminated structure in which a plurality of insulating films are laminated or may have a single layer structure which is constituted of a single insulating film. The interlayer insulating film 72 may include at least one of a silicon oxide film, a silicon nitride film, and a silicon oxynitride film. The interlayer insulating film 72 covers the plurality of trench separation structures 20, the plurality of trench gate structures 30, the plurality of dummy trench structures 40, the field insulating film 70, and the main surface insulating film 71. In this embodiment, the interlayer insulating film 72 covers an entire area of the first main surface 3 and continues to the first to fourth side surfaces 5A to 5D.

The semiconductor device 1A includes a plurality of via electrodes 80 which are embedded in the interlayer insulating film 72. The plurality of via electrodes 80 include a plurality of gate via electrodes 81, a plurality of first source via electrodes 82, and a plurality of second source via electrodes 83.

The plurality of gate via electrodes 81 penetrate through the interlayer insulating film 72 and are each electrically connected to the corresponding upper electrode 37 at both end portions 30a, 30b sides of the corresponding trench gate structure 30. The plurality of gate via electrodes 81 are arrayed at an interval in the first direction X and the second direction Y in plan view and face in the first direction X and second direction Y. A position of connecting the plurality of gate via electrodes 81 with the upper electrode 37 is arbitrary. The plurality of gate via electrodes 81 are not necessarily arrayed on the same line extending in the first direction X in plan view but may be arrayed so as to be offset from each other in the second direction Y.

The plurality of first source via electrodes 82 penetrate through the interlayer insulating film 72 and are each embedded inside the plurality of contact holes 61. The plurality of first source via electrodes 82 are electrically connected to the second region 7, the plurality of source regions 60, and the plurality of contact regions 62 inside the plurality of contact holes 61.

The plurality of second source via electrodes 83 penetrate through the interlayer insulating film 72 and are electrically connected to the separation electrode 23 of the trench separation structure 20 (lead-out portion 39 of trench gate structure 30). That is, the plurality of second source via electrodes 83 are electrically connected to the lower electrodes 36 of the plurality of trench gate structures 30 via the separation electrode 23. The plurality of second source via electrodes 83 are arrayed as dots at an interval along the separation electrode 23 in plan view. As a matter of course, the plurality of via electrodes 80 may include one or the plurality of second source via electrodes 83 extending in a band shape along the separation electrode 23 in plan view.

The semiconductor device 1A includes a gate wiring electrode 90 which is arranged on the plurality of gate via electrodes 81 and transmits a gate potential. Specifically, the gate wiring electrode 90 is arranged on the interlayer insulating film 72. The gate wiring electrode 90 includes a gate pad electrode 91 and a gate finger electrode 92. The gate pad electrode 91 is a terminal electrode which is externally connected to a conductive connecting member (for example, bonding wire, conductive plate, etc.). A gate potential is to be imparted to the gate pad electrode 91.

The gate pad electrode 91 is formed in a quadrilateral shape on a portion along a central portion of the third side surface 5C in plan view. Specifically, the gate pad electrode 91 overlaps with the pad region 10b of the outer region 10 in plan view. That is, the gate pad electrode 91 overlaps with the outer diode D2 in plan view. The gate pad electrode 91 is preferably arranged at an interval from the trench separation structure 20 to the pad region 10b side in plan view. The gate pad electrode 91 preferably does not overlap with the trench separation structure 20, the trench gate structure 30, and the dummy trench structure 40 in plan view. An entire area of the gate pad electrode 91 preferably overlaps with the outer diode D2 in plan view.

The gate finger electrode 92 is led out onto the interlayer insulating film 72 from the gate pad electrode 91. The gate finger electrode 92 extends in a band shape along a peripheral edge of the device region 9 so as to intersect (specifically, orthogonal to) the plurality of trench gate structures 30 in plan view. The gate finger electrode 92 needs only to extend along at least two of the first to fourth side surfaces 5A to 5D (first to fourth trench separation structures 20A to 20D) in plan view. In this embodiment, the gate finger electrode 92 extends along the first side surface 5A (first trench separation structure the second side surface 5B (second trench separation structure 20B), and the third side surface 5C (third trench separation structure 20C) in plan view and intersects (specifically, orthogonal to) both end portions 30a, 30b of the plurality of trench gate structures 30.

The gate finger electrode 92 partially overlaps with the plurality of inner diodes D1 in plan view. The gate finger electrode 92 may overlap with the plurality of dummy trench structures 40 in plan view. In this case, the gate finger electrode 92 may partially overlap with the plurality of intermediate diodes D3 in plan view. The gate finger electrode 92 is connected to the plurality of gate via electrodes 81. The gate finger electrode 92 imparts a gate potential applied to the gate pad electrode 91 to the plurality of gate via electrodes 81.

The semiconductor device 1A includes a source wiring electrode 93 which is arranged on the plurality of first and second source via electrodes 82 and 83 and transmits a source potential. The source wiring electrode 93 is arranged on the same layer as the gate wiring electrode (that is, on the interlayer insulating film 72) at an interval from the gate wiring electrode 90 and faces the gate wiring electrode 90 in a lateral direction along the first main surface 3. The source wiring electrode 93 includes a source pad electrode 94 and a source finger electrode 95.

The source pad electrode 94 is a terminal electrode which is externally connected to a conductive connecting member (for example, bonding wire, conductive plate, etc.). The source pad electrode 94 is arranged in a region which is demarcated by the gate wiring electrode 90 in plan view and overlaps with the device region 9. In this embodiment, the source pad electrode 94 is formed in a polygonal shape having a recessed portion which is recessed toward the fourth side surface 5D side from a central portion of a side along the third side surface 5C so as to align with the gate pad electrode 91 (pad region 10b) in plan view.

The source pad electrode 94 overlaps with the plurality of trench gate structures 30 and the plurality of dummy trench structures 40 in plan view. That is, the source pad electrode 94 overlaps with the plurality of inner diodes D1 and the plurality of intermediate diodes D3. The source pad electrode 94 is connected to the plurality of first source via electrodes 82. A source potential which is applied to the source pad electrode 94 is to be imparted via the plurality of first source via electrodes 82 individually to the second region 7, the plurality of source regions 60, and the plurality of contact regions 62.

The source finger electrode 95 is led out onto the same layer as the gate wiring electrode 90 (that is, on the interlayer insulating film 72) from the source pad electrode 94. The source finger electrode 95 is led out in a region between the peripheral edge portion of the first main surface 3 and the gate finger electrode 92 from the source pad electrode 94 in plan view and extends in a band shape along the trench separation structure 20. The source finger electrode 95 needs only to extend along at least two of the first to fourth side surfaces 5A to 5D (first to fourth trench separation structures 20A to 20D) in plan view.

In this embodiment, the source finger electrode 95 extends along the first to fourth side surfaces 5A to 5D (first to fourth trench separation structures 20A to 20D) in plan view. In this embodiment, the source finger electrode 95 is formed in an annular shape which surrounds the gate pad electrode 91, the gate finger electrode 92, and the source pad electrode 94 in plan view.

The source finger electrode 95 partially overlaps with the plurality of inner diodes D1, the outer diode D2, and the intermediate diode D3 in a plan view. The source finger electrode 95 is connected to the plurality of second sources via electrodes 83. The source finger electrode 95 imparts a source potential applied to the source pad electrode 94 to the plurality of second source via electrodes 83. The source potential imparted to the plurality of second source via electrodes 83 is to be imparted to the lower electrodes 36 of the plurality of trench gate structures 30 via the separation electrode 23 (lead-out portion 39).

The semiconductor device 1A includes a drain electrode 96 which covers the second main surface 4. In this embodiment, the drain electrode 96 covers an entire area of the second main surface 4 and continues to a peripheral edge of the first main surface 3 (first to fourth side surfaces 5A to 5D). The drain electrode 96 is electrically connected to the third region 8.

As described above, the semiconductor device 1A includes the chip 2, the first region 6, the second region 7, the trench separation structure 20, the trench gate structure 30, the inner diode D1, and the outer diode D2. The chip 2 has the first main surface 3. The first region 6 is formed in the surface layer portion of the first main surface 3. The second region 7 is formed in the surface layer portion of the first region 6. The trench separation structure 20 is formed in an annular shape in the first main surface 3 so as to surround an interior of the second region 7 in plan view and penetrates through the second region 7 in a cross-sectional view. The trench separation structure demarcates the device region 9 at an inner side of the second region 7 (inner region) and the outer region 10 at an outer side of the second region 7 in the first main surface 3.

The trench gate structure 30 is formed in the device region 9 so as to penetrate through the second region 7. The inner diode D1 includes the first region 6 and the second region 7 which are positioned in the device region 9. The outer diode D2 includes the first region 6 and the second region 7 which are positioned in the outer region 10. The outer diode D2 is electrically separated from the trench gate structure 30 and the inner diode D1 by the trench separation structure 20.

Where the outer diode D2 is electrically connected to the inner diode D1, the electrical characteristics at the device region 9 side are restricted by the electrical characteristics at the router region 10 side. As an example, a withstand voltage (specifically, breakdown voltage) at the outer region 10 side is made smaller than a withstand voltage (specifically, breakdown voltage) at the device region 9 side by such an extent that the trench gate structure 30 is not provided. Consequently, at the time of applying the breakdown voltage, the outer region 10 (outer diode D2) serves as a starting point of breakdown.

On the other hand, according to a structure in which the outer diode D2 is electrically separated from the trench gate structure 30 and the inner diode D1, the electrical characteristics at the device region 9 side are separated from the electrical characteristics at the outer region 10 side. Thereby, the electrical characteristics at the device region 9 can be prevented from being restricted by the electrical characteristics at the outer region 10 side. It is therefore possible to provide the semiconductor device 1A capable of improving the electrical characteristics. As an example, there can be provided the semiconductor device 1A capable of improving the breakdown voltage.

The outer diode D2 is preferably constituted of a floating diode which is formed in an electrically floating state. According to this structure, it is possible to appropriately suppress an electrical influence of the outer region 10 on the device region 9. The outer diode D2 may surround the trench separation structure 20 in plan view.

The chip 2 may have the first to fourth side surfaces 5A to 5D. In this case, the first region 6 may be exposed from at least one of the first to fourth side surfaces 5A to 5D. The second region 7 may be exposed from at least one of the first to fourth side surfaces 5A to 5D. That is, the outer diode D2 may be exposed from at least one of the first to fourth side surfaces 5A to 5D.

Where the outer diode D2 is electrically connected to the inner diode D1 in a structure in which the second region 7 is exposed from at least one of the first to fourth side surfaces 5A to 5D, the outer diode D2 is increased in area. An electrical influence of the outer region 10 on the device region 9 is consequently increased.

In contrast thereto, where the outer diode D2 is electrically separated from the inner diode D1, the electrical influence of the outer region 10 on the device region 9 can be suppressed, it is therefore possible to form the second region 7 (outer diode D2) which is exposed from at least one of the first to fourth side surfaces 5A to 5D. That is, it is possible to relax design rules imposed on the second region 7, while improving the electrical characteristics. In this case, the second region 7 may be exposed from all of the first to fourth side surfaces 5A to According to this structure, it is possible to form the second region 7 without using a resist mask, and therefore it is possible to reduce costs.

The trench gate structure 30 preferably has a multi-electrode structure that includes, inside the gate trench 31, the lower electrode 36 and the upper electrode 37 which are separated and embedded in an up/down direction. In this case, the second region 7 of the inner diode D1 is preferably electrically connected to the lower electrode 36. The plurality of trench gate structures 30 may be arrayed as a stripe shape in the device region 9.

The trench separation structure 20 may include the separation electrode 23 which is embedded inside the separation trench 21. In this case, the second region 7 of the inner diode D1 is preferably electrically connected to the separation electrode 23. The trench separation structure 20 preferably has an inner structure different from the trench gate structure 30. The trench separation structure 20 preferably has a single electrode structure which includes the single separation electrode 23.

The semiconductor device 1A preferably includes the source region 60 (impurity region) in the device region 9. The source region 60 is preferably formed in the surface layer portion of the first main surface 3 so as to be in contact with the trench gate structure 30. The source region 60 is preferably formed at an interval from the trench separation structure 20 so as not to be in contact with the trench separation structure 20. With this structure, it is possible to suppress undesirable current paths.

The semiconductor device 1A preferably includes the dummy trench structure 40 which is formed in a region between the trench separation structure 20 and the trench gate structure 30 in the device region 9. The dummy trench structure 40 is preferably formed so as to penetrate through the second region 7 and electrically separated from the trench gate structure 30. According to this structure, it is possible to relax a stress generated between the trench separation structure 20 and the trench gate structure 30 by the dummy trench structure 40. It is thereby possible to suppress fluctuations in electrical characteristics at the device region 9 side resulting from the stress generated between the trench separation structure 20 and the trench gate structure 30.

The dummy trench structure 40 preferably has an inner structure different from the trench gate structure 30. The dummy trench structure 40 preferably has an inner structure different from the trench separation structure 20. The dummy trench structure 40 may include the dummy electrode 43 which is embedded at the bottom side of the dummy trench 41 and the embedded insulator 44 which is embedded at the opening side of the dummy trench 41. The dummy trench structure 40 preferably does not include an electrode which faces the dummy electrode 43 across the embedded insulator 44 inside the dummy trench 41.

The semiconductor device 1A may include the intermediate diode D3 which includes the first region 6 and the second region 7 positioned at a region between the trench separation structure 20 and the dummy trench structure 40 in the device region 9. The intermediate diode D3 is preferably electrically separated from the outer diode D2 by the trench separation structure 20. The intermediate diode D3 may be electrically separated from the inner diode D1 by the dummy trench structure 40. According to this structure, the intermediate diode D3 serves as a buffer between the inner diode D1 and the outer diode D2, and the inner diode D1 and the outer diode D2 are therefore electrically separated appropriately.

In another point of view, the semiconductor device 1A includes the chip 2, the trench separation structure 20, the trench gate structure 30, the first body region 7A, and the second body region 7B. The chip 2 has the first main surface 3. The trench separation structure is formed in the first main surface 3 as a band shape extending in the first direction X. The trench gate structure 30 is formed in the first main surface 3 as a band shape extending in the second direction Y that intersects the first direction X and demarcates the mesa portion 50 (first mesa portion 50A) with the trench separation structure 20.

The first body region 7A is formed in the surface layer portion of the first main surface 3 inside the mesa portion 50. The second body region 7B is formed in the surface layer portion of the first main surface 3 outside the mesa portion 50. The second body region 7B is electrically separated from the first body region 7A by the trench separation structure 20. According to this structure, the electrical characteristics at the first body region 7A side can be prevented from being restricted by the electrical characteristics at the second body region 7B side. It is therefore possible to provide the semiconductor device 1A capable of improving the electrical characteristics.

The first body region 7A is preferably in contact with the trench gate structure 30. The second body region 7B is preferably in contact with the trench separation structure 20. The second body region 7B is preferably formed in an electrically floating state. According to this structure, it is possible to appropriately suppress an electrical influence of the second body region 7B on the first body region 7A. In this case, it is preferable that a source potential is to be imparted to the first body region 7A.

The pair of trench separation structures 20 are preferably arrayed in the first main surface 3 at an interval in the second direction Y. In this case, it is preferable that the trench gate structure 30 is formed in a region sandwiched between the pair of trench separation structures 20 and demarcates the mesa portion 50 with the pair of trench separation structures 20. In this case, it is preferable that the pair of trench gate structures 30 are arrayed in the region sandwiched between the pair of trench separation structures 20 at an interval in the first direction X and demarcates the mesa portion 50 with the pair of trench separation structures 20.

The first body region 7A is preferably in contact with the pair of trench separation structures 20 and the trench gate structure 30 inside the mesa portion 50. The first body region 7A preferably extends as a band shape along the trench gate structure 30 in plan view. The second body region 7B is preferably in contact with one or both of the pair of trench separation structures 20 outside the mesa portion 50. The second body region 7B preferably surrounds the trench separation structure 20 and the trench gate structure 30 in plan view.

The chip 2 may have the first to fourth side surfaces 5A to 5D. In this case, the second body region 7B may be exposed from at least one of the first to fourth side surfaces 5A to 5D or may be exposed from all of the first to fourth side surfaces 5A to 5D.

The semiconductor device 1A preferably includes the source region 60 (impurity region) which is formed in a surface layer portion of the first body region 7A. The source region 60 is preferably in contact with the trench gate structure 30. The source region 60 is preferably not formed in a surface layer portion of the second body region 7B. The source region 60 preferably extends as a band shape along the trench gate structure 30 in plan view. The source region 60 is preferably formed at an interval from the trench separation structure 20 so as not to be in contact with the trench separation structure 20. With this structure, it is possible to suppress undesirable current paths.

The semiconductor device 1A preferably includes the dummy trench structure 40 which is arranged so as to extend in the second direction Y at an interval from the trench gate structure 30 in the first direction X and electrically separated from the trench gate structure 30. In this case, the second body region 7B is preferably electrically separated from the dummy trench structure 40. The first body region 7A may be electrically separated from the dummy trench structure 40.

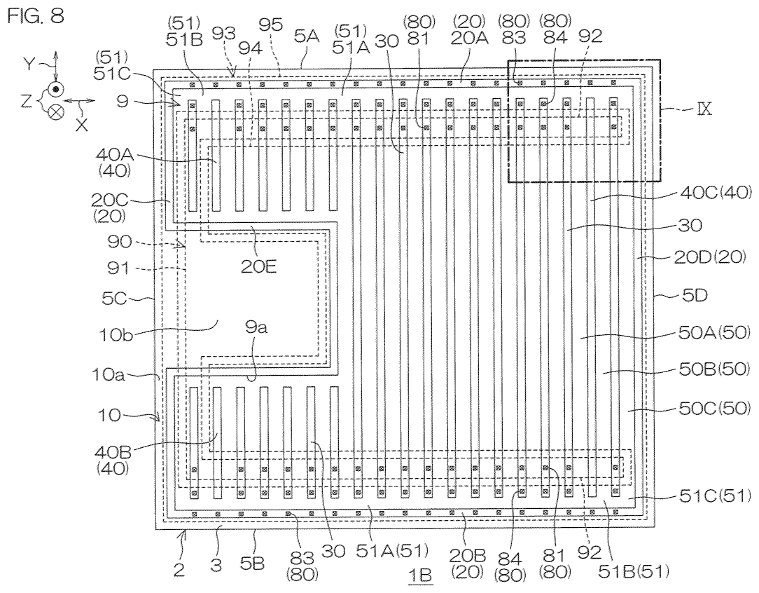

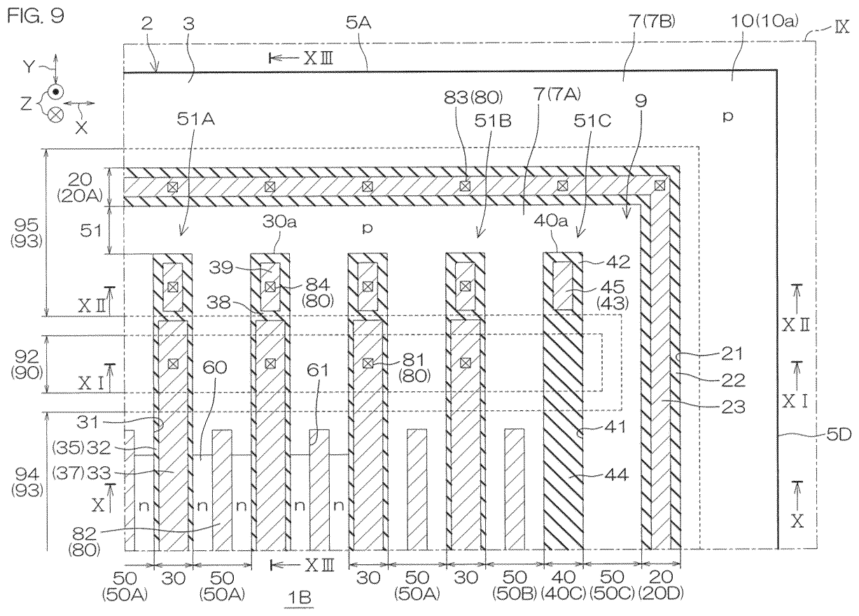

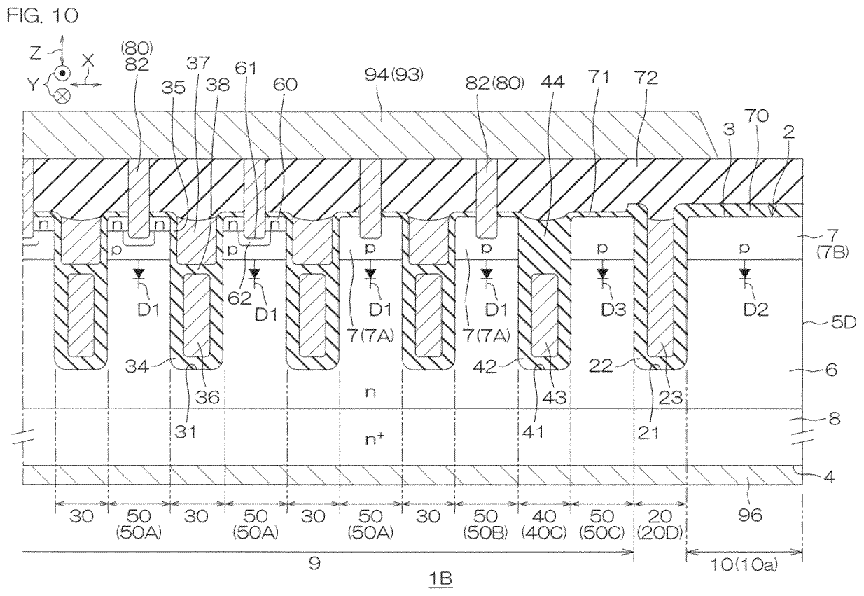

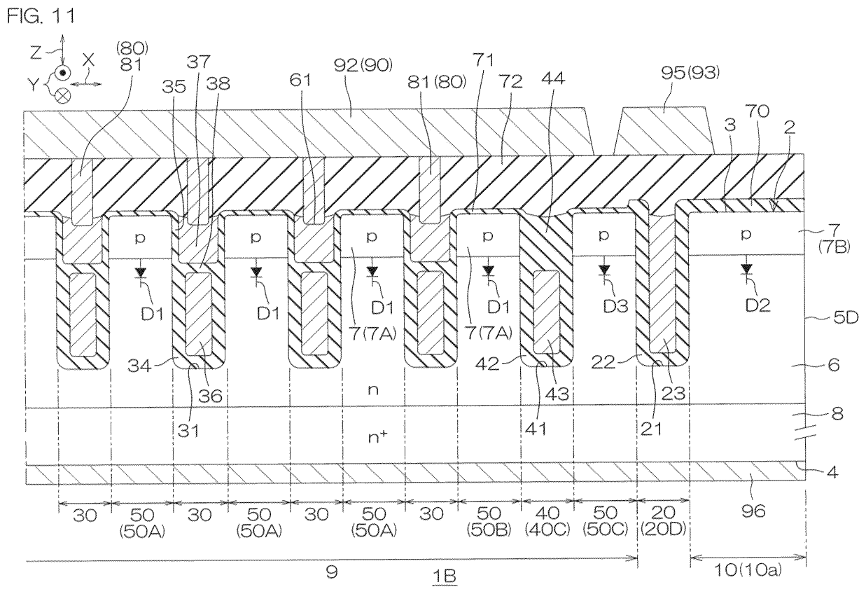

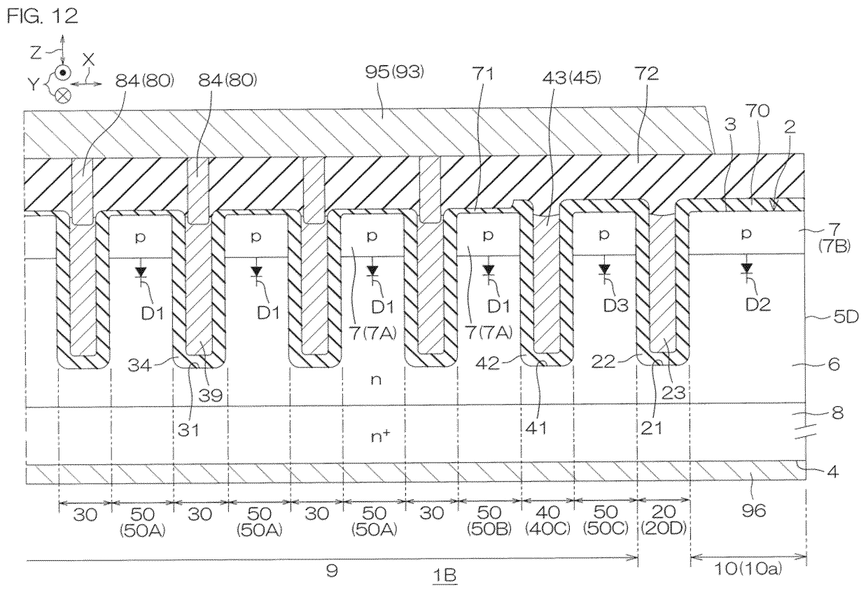

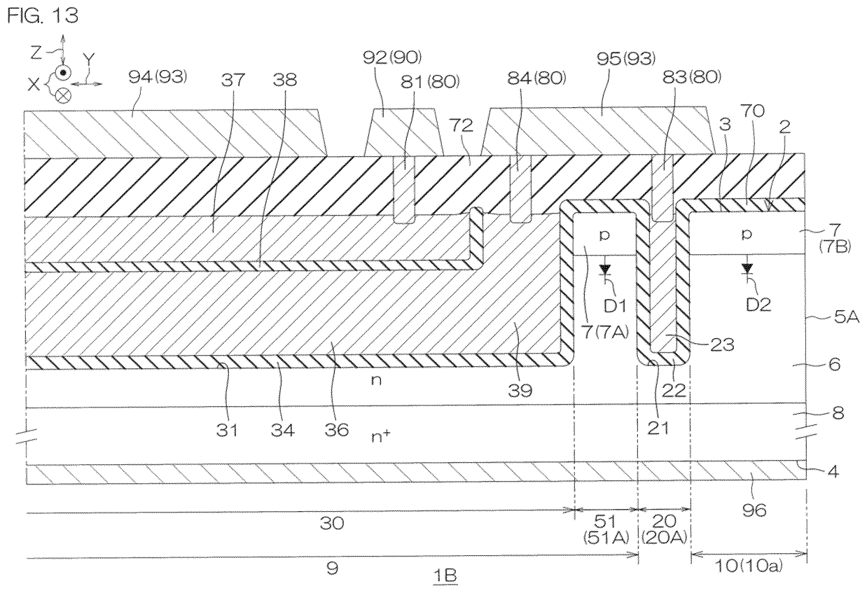

FIG. 8 corresponds to FIG. 2 and is a plan view which shows a structure of the first main surface 3 of the chip 2 in a semiconductor device 1B according to a second embodiment. FIG. 9 is an enlarged view of a region IX shown in FIG. 8. FIG. 10 is a cross-sectional view taken along line X-X shown in FIG. 9. FIG. 11 is a cross-sectional view taken along line XI-XI shown in FIG. 9. FIG. 12 is a cross-sectional view taken along line XII-XII shown in FIG. 9. FIG. 13 is a cross-sectional view taken along line XIII-XIII shown in FIG. 9.

With reference to FIG. 8 to FIG. 13, in this embodiment, the plurality of trench gate structures 30 are formed in the first main surface 3 at an interval from the trench separation structure 20 in the device region 9. Specifically, the plurality of trench gate structures 30 are formed at an interval in the second direction Y from the pair of trench separation structures 20 (first trench separation structure 20A and second trench separation structure 20B) extending in the first direction X. That is, the plurality of trench gate structures 30 each have the first end portion 30a at one side which is separated from the trench separation structure 20 in the second direction Y and the second end portion 30b at the other side which is separated from the trench separation structure 20 in the second direction Y.

An interval between the trench separation structure 20 and the trench gate structure 30 (both end portions 30a, 30b) is preferably set in such a range that a depletion layer covers a bottom wall of the trench separation structure 20 and a bottom wall of the trench gate structure 30. The plurality of trench gate structures 30 may be formed at an interval of not less than 0.1 μm and not more than 2 μm (preferably, not less than 0.5 μm and not more than 1.5 μm) from the trench separation structure with regard to the second direction Y. The interval between the trench separation structure 20 and the trench gate structure 30 may be substantially equal to an interval between the plurality of trench gate structures 30.

In this embodiment, the plurality of dummy trench structures 40 are formed in the first main surface 3 at an interval from the trench separation structure 20 in the device region 9. Specifically, the plurality of dummy trench structures 40 are formed at an interval in the second direction Y from the pair of trench separation structures (first trench separation structure 20A and second trench separation structure 20B) extending in the first direction X.

That is, the plurality of dummy trench structures each have the first end portion 40a at one side which is separated from the trench separation structure 20 in the second direction Y and the second end portion 40b at the other side which is separated from the trench separation structure 20 in the second direction Y. In this embodiment, the plurality of dummy trench structures 40 are electrically separated from the plurality of trench gate structures 30 and the trench separation structure 20. In this embodiment, the plurality of dummy trench structures 40 are formed in an electrically floating state.

An interval between the trench separation structure 20 and the dummy trench structure 40 (both end portions 40a, 40b) is preferably set in such a range that a depletion layer covers a bottom wall of the trench separation structure 20 and a bottom wall of the dummy trench structure 40. The plurality of dummy trench structures 40 may be formed from the trench separation structure 20 at an interval of not less than 0.1 μm and not more than 2 μm (preferably, not less than 0.5 μm and not more than 1.5 μm) with regard to the second direction Y. The interval between the trench separation structure 20 and the dummy trench structure 40 is preferably substantially equal to the interval between the trench separation structure 20 and the trench gate structure 30.

In this embodiment, the semiconductor device 1B includes a pair of mesa connecting portions 51 which connect both end portions of the plurality of mesa portions 50 in the device region 9. The pair of mesa connecting portions 51 are each demarcated in a region between the trench separation structure 20 and the plurality of trench gate structures 30 and in a region between the trench separation structure 20 and the plurality of dummy trench structures 40. The pair of mesa connecting portions 51 are each constituted of a part of the chip 2 and each include the first region 6 and the second region 7. The pair of mesa connecting portions 51 extend as a band shape in a direction (first direction X) which intersects (specifically, orthogonal to) a direction (second direction Y) in which the plurality of mesa portions 50 extend in plan view.

Specifically, the pair of mesa connecting portions 51 include plural pairs of first mesa connecting portions 51A, plural pairs of second mesa connecting portions 51B, and a plurality of third mesa connecting portions 51C. The pair of first mesa connecting portions 51A connect both end portions of the first mesa portions mutually adjacent in the first direction X. The pair of first mesa connecting portions 51A constitute one annular mesa portion which surrounds one trench gate structure 30 with the pair of first mesa portions 50A in plan view. The plural pairs of first mesa connecting portions 51A are integrally formed in the first direction X. Thereby, the plural pairs of first mesa connecting portions 51A constitute a ladder-shaped mesa portion which surrounds the plurality of trench gate structures 30 with the plurality of first mesa portions 50A in plan view.

The pair of second mesa connecting portions 51B connect both end portions of the first mesa portion 50A and the second mesa portion 50B which are mutually adjacent in the first direction X. The pair of second mesa connecting portions 51B constitute one annular mesa portion which surrounds one trench gate structure 30 with the first mesa portion 50A and the second mesa portion 50B which are mutually adjacent in the first direction X in plan view. The plural pairs of second mesa connecting portions 51B are integrally formed with the plural pairs of first mesa connecting portions 51A in the first direction X. Thereby, the plural pairs of second mesa connecting portions 51B constitute a ladder-shaped mesa portion which surrounds the plurality of trench gate structures 30 with the plural pairs of first mesa connecting portions 51A, the plurality of first mesa portions 50A, and the plurality of second mesa portions 50B in plan view.

The pair of third mesa connecting portions 51C connect both end portions of the second mesa portion 50B and the third mesa portion 50C which are mutually adjacent in the first direction X. The pair of third mesa connecting portions 51C constitute one annular mesa portion which surrounds one dummy trench structure 40 with the second mesa portion 50B and the third mesa portion 50C which are mutually adjacent in the first direction X in plan view. The plural pairs of third mesa connecting portions 51C are integrally formed with the plural pairs of first mesa connecting portions 51A and the plural pairs of second mesa connecting portions 51B in the first direction X. Thereby, the plural pairs of third mesa connecting portions 51C constitute a ladder-shaped mesa portion which surrounds the plurality of trench gate structures 30 and the plurality of dummy trench structures 40 with the plural pairs of first mesa connecting portions 51A, the plural pairs of second mesa connecting portions 501B, the plurality of first mesa portions 50A, and the plurality of second mesa portions 50B in plan view.

In this embodiment, the plurality of inner diodes D1 are electrically connected to each other via the pair of mesa connecting portions 51 (specifically, first and second mesa connecting portions 51A and 51B). That is, the plurality of inner diodes D1 are formed in annular shapes (quadrilateral annular shapes in this embodiment) which surrounds the plurality of trench gate structures 30 inside the device region 9. As with the above-described first embodiment, the outer diode D2 is electrically separated from the plurality of inner diodes D1 by the trench separation structure 20.

In this embodiment, the plurality of intermediate diodes D3 are electrically connected to the plurality of inner diodes D1 via the pair of mesa connecting portions 51 (specifically, first to third mesa connecting portions 51A to 51C). That is, the plurality of intermediate diodes D3 are formed in annular shapes (quadrilateral annular shapes in this embodiment) which surrounds the plurality of dummy trench structures 40 together with the plurality of inner diodes D1 inside the device region 9. Further, in this embodiment, as with the inner diode D1, the plurality of intermediate diodes D3 are electrically connected between a source and a drain and function as a body diode of a MISFET.

In this embodiment, the field insulating film 70 covers the plurality of mesa connecting portions 51 in the device region 9. The field insulating film 70 continues to the gate insulating films 32 (lower insulating film 34) of the plurality of trench gate structures 30 and the dummy insulating films 42 (embedded insulator 44) of the plurality of dummy trench structures 40 at the plurality of mesa connecting portions 51.

In this embodiment, the plurality of via electrodes 80 include a plurality of third source via electrodes 84 which penetrate through the interlayer insulating film 72 and are each electrically connected to the plurality of lead-out portions 39 of the corresponding trench gate structure 30. The plurality of third source via electrodes 84 are arrayed at an interval in the first direction X and the second direction Y in plan view and face in the first direction X and the second direction Y. A position at which the plurality of third source via electrodes 84 are connected to the plurality of lead-out portions 39 is arbitrary. The plurality of third source via electrodes 84 are not necessarily arrayed on the same line extending in the first direction X in plan view but may be arrayed so as to be offset from each other in the second direction Y.

In this embodiment, the source finger electrode is connected to the plurality of second source via electrodes 83 and the plurality of third source via electrodes 84. The source finger electrode 95 imparts a source potential which is applied to the source pad electrode 94 to the plurality of second source via electrodes 83 and the plurality of third source via electrodes 84. The source potential imparted to the plurality of second source via electrodes 83 is to be imparted to the separation electrode 23. The source potential imparted to the plurality of third source via electrodes 84 is to be imparted to the lower electrodes 36 of the plurality of trench gate structures 30 via the plurality of lead-out portions 39.

As described above, the same effects as the effects described for the semiconductor device 1A can be exhibited also by the semiconductor device 1B.

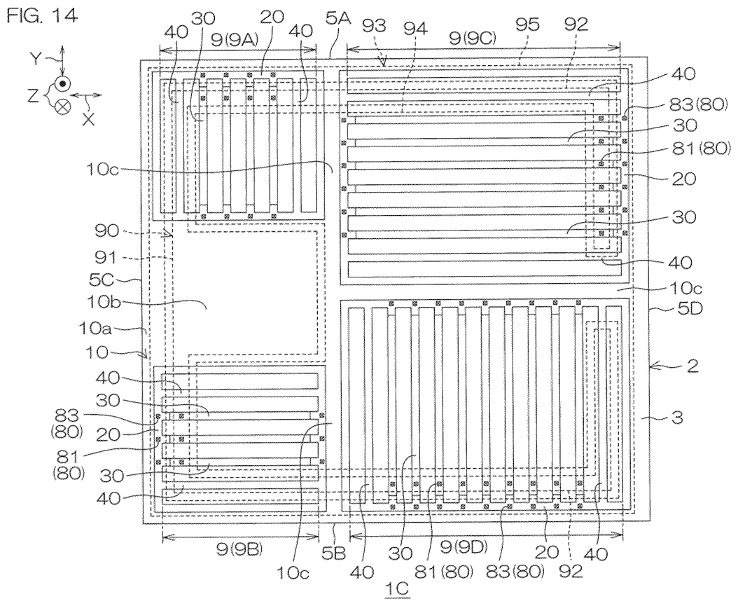

FIG. 14 corresponds to FIG. 2 and is a plan view which shows a structure of the first main surface 3 of the chip 2 in a semiconductor device 1C according to a third embodiment. With reference to FIG. 14, the semiconductor device 1C includes the plurality of (four in this embodiment) device regions 9 set at an internal portion of the first main surface 3 (inner region). The four device regions 9 include a first device region 9A, a second device region 9B, a third device region 9C, and a fourth device region 9D. The number of the device regions 9 and a arrangement thereof are arbitrary and adjusted according to a size of the first main surface 3 and electrical characteristics of a MISFET to be accomplished. Hereinafter, a description of one arrangement example of the plurality of device regions 9 shall be given.

The first device region 9A is set along a corner which connects the first side surface 5A and the third side surface 5C in plan view. The first device region 9A is set to a quadrilateral shape in plan view. The second device region 9B is set along a corner which connects the second side surface 5B and the third side surface 5C at an interval from the first device region 9A in the second direction Y in plan view.

The third device region 9C is set along a corner which connects the first side surface 5A and the fourth side surface 5D at an interval from the first device region 9A in the first direction X. The third device region 9C is set to a quadrilateral shape larger than the first and second device regions 9A and 9B in plan view. In this embodiment, the third device region 9C faces the first device region 9A in the first direction X in plan view but does not face the second device region 9B.

The fourth device region 9D is set along a corner which connects the second side surface 5B and the fourth side surface 5D at an interval from the second device region 9B in the first direction X and at an interval from the third device region 9C in the second direction Y. The fourth device region 9D is set to a quadrilateral shape larger than the first and second device regions 9A and 9B in plan view. In this embodiment, the fourth device region 9D faces the second device region 9B in the first direction X in plan view but does not face the first device region 9A.

In this embodiment, the outer region 10 includes the annular region 10a, the pad region 10b, and an intermediate region 10c. In this embodiment, the annular region 10a is set to an annular shape (specifically, quadrilateral annular shape) which extends along a peripheral edge of the first main surface 3 (first to fourth side surfaces 5A to 5D) in plan view and collectively surrounds the plurality of device regions 9. In this embodiment, the pad region 10b is set in a region between the first device region 9A and the second device region 9B in plan view and protrudes toward the fourth side surface from a portion of the annular region 10a along a central portion of the third side surface 5C. In this embodiment, the pad region 10b is set to a quadrilateral shape in plan view.

The intermediate region 10c is set in a region between the plurality of device regions 9 in plan view. In this embodiment, the intermediate region 10c is set to a band shape having a portion extending in the first direction X and a portion extending in the second direction Y. Where the semiconductor device 1C includes two device regions 9 which are set at an interval in the first direction X or in the second direction Y, the intermediate region 10c may be set to a band shape extending in the first direction X or in the second direction Y.

The plurality of device regions 9 are each surrounded by the above-described plurality of trench separation structures 20 and each demarcated from the outer region 10. That is, as with a case of the above-described first embodiment, the plurality of trench separation structures 20 separate the second region 7 into a plurality of portions (plurality of first body regions 7A) positioned inside the plurality of device regions 9 and a portion (second body region 7B) positioned inside the outer region 10.

In the plurality of device regions 9, there are individually formed the above-described plurality of trench gate structure 30, the plurality of dummy trench structures 40, the plurality of inner diodes D1, the plurality of intermediate diodes D3, the plurality of source regions 60, the plurality of contact holes 61, the plurality of contact regions 62, the field insulating film 70, the main surface insulating film 71, the interlayer insulating film 72, the plurality of gate via electrodes 81, the plurality of first source via electrodes 82, and the plurality of second source via electrodes 83.

A planar shape of each trench separation structure 20 is adjusted according to a planar shape of each device region 9. The number of the trench gate structures which are formed inside each device region 9 is arbitrary and adjusted according to a size of each device region 9. In this embodiment, the plurality of trench gate structures 30 each extend in a different direction (first direction X or second direction Y) in the plurality of device regions 9. In this embodiment, the plurality of dummy trench structures 40 extend along the plurality of trench gate structures 30 inside each device region 9 and sandwich the plurality of trench gate structures 30 from both sides in the first direction X or from both sides in the second direction Y.

In the first device region 9A, the plurality of trench gate structures 30 are arrayed at an interval in the first direction X in plan view and each is formed in a band shape extending in the second direction Y. That is, in the first device region 9A, the plurality of trench gate structures 30 are arrayed as a stripe shape extending in the second direction Y in plan view. In the second device region 9B, the plurality of trench gate structures 30 are arrayed at an interval in the second direction Y in plan view and each is formed in a band shape extending in the first direction X. That is, in the second device region 9B, the plurality of trench gate structures 30 are arrayed as a stripe shape extending in the first direction X in plan view.

In the third device region 9C, as with the second device region 9B, the plurality of trench gate structures are arrayed as a stripe shape extending in the first direction X in plan view. In the fourth device region 9D, as with the first device region 9A, the plurality of trench gate structures 30 are arrayed as a stripe shape extending in the second direction Y.

That is, the plurality of trench gate structures 30 extend in a direction different from each other in the first device region 9A and the second device region 9B which face in the second direction Y. The plurality of trench gate structures 30 also extend in a direction different from each other in the third device region 9C and the fourth device region 9D which face in the second direction Y. Further, the plurality of trench gate structures 30 extend in a direction different from each other in the first device region 9A and the third device region 9C which face in the first direction X. Still further, the plurality of trench gate structures 30 extend in a direction different from each other in the second device region 9B and the fourth device region 9D which face in the first direction X.

In other words, the plurality of trench gate structures 30 extend in one direction in the first device region 9A and the fourth device region 9D which face in one diagonal direction of the first main surface 3 and extend in a direction that intersects one direction in the second device region 9B and the third device region 9C which face in another diagonal direction of the first main surface 3.

That is, the semiconductor device 1C includes at least one trench gate structure 30 which extends in the first direction X in a different region of the first main surface 3 (the plurality of device regions 9) and at least one trench gate structure 30 which extends in the second direction Y which intersects (specifically, orthogonal to) the first direction X. At least one trench gate structure 30 which extends in the first direction X may face at least one trench gate structure 30 which extends in the first direction X in one of or in both of the first direction X and the second direction Y.

At least one trench gate structure 30 which extends in the second direction Y may face at least one trench gate structure 30 which extends in the second direction Y in one of or in both of the first direction X and the second direction Y. At least one trench gate structure 30 which extends in the second direction Y may face at least one trench gate structure 30 which extends in the first direction X in one of or in both of the first direction X and the second direction Y.

In this embodiment, the outer diode D2 has the first region 6 and the second region 7 (second body region 7B) which are positioned in a region outside the plurality of device regions 9 (outer region 10). That is, in this embodiment, the outer diode D2 is formed in the annular region 10a, the pad region 10b, and the intermediate region 10c. That is, the outer diode D2 is formed in an annular shape that collectively surrounds the plurality of device regions 9 in plan view.

Further, the outer diode D2 is formed in an annular shape that individually surrounds each of the plurality of device regions 9 in plan view. As with a case of the first embodiment, the outer diode D2 may be exposed from at least one of the first to fourth side surfaces 5A to 5D. In this embodiment, the outer diode D2 is formed in an entire area of a region outside the plurality of device regions 9 in the first main surface 3.

In this embodiment, the field insulating film 70 covers the outer diode D2 in the annular region 10a, the pad region 10b, and the intermediate region 10c of the outer region 10. The field insulating film 70 preferably covers an entire area of the outer diode D2. As a matter of course, the field insulating film 70 may partially cover the outer diode D2, and the main surface insulating film 71 may cover a portion exposed from the field insulating film 70 in the outer diode D2.

A gate pad electrode 91 is arranged on the interlayer insulating film 72 in the same manner as the first embodiment. In this embodiment, the gate finger electrode 92 is formed in a band shape which crosses the plurality of device regions 9 so as to intersect (specifically, orthogonal to) the plurality of trench gate structures 30 arranged in the plurality of device regions 9 in plan view. The gate finger electrode 92 is electrically connected to the plurality of trench gate structures 30 (upper electrode 37) via the plurality of gate via electrodes 81 in the plurality of device regions 9. The manner of routing the gate finger electrode 92 is arbitrary.

In this embodiment, the source pad electrode 94 is arranged in a region demarcated by the gate wiring electrode 90 in plan view and overlaps with the plurality of device regions 9. The source pad electrode 94 is connected to the plurality of first source via electrodes 82. The source pad electrode 94 is electrically connected to the second region 7, the plurality of source regions 60, and the plurality of contact regions 62 via the plurality of first source via electrodes 82 in the plurality of device regions 9.

In this embodiment, the source finger electrode is formed in a band shape extending along the plurality of trench separation structures 20 which are arranged in the plurality of device regions 9 in plan view. The source finger electrode 95 is electrically connected to the plurality of separation electrodes 23 via the plurality of second source via electrodes 83 in the plurality of device regions 9. The manner of routing the source finger electrode 95 is arbitrary.

As described above, in the semiconductor device 1C, the plurality of device regions 9 are each electrically connected to the gate wiring electrode 90, the source wiring electrode 93, and the drain electrode 96. That is, functional devices (MISFET and inner diode D1) formed in the plurality of device regions 9 are driven and controlled at the same timing. As described above, the same effects as the effects described for the semiconductor device 1A can be exhibited also by the semiconductor device 1C. The trench gate structure 30 according to the above-described second embodiment may be applied to the semiconductor device 1C according to the third embodiment. In this case, the source wiring electrode 93 is electrically connected to the first to third source via electrodes 82 to 84 in the plurality of device regions 9.

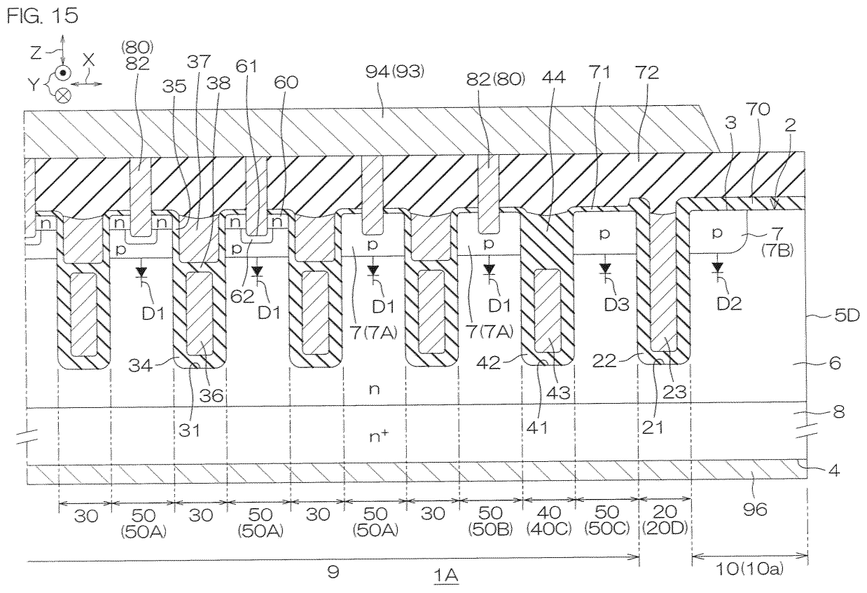

Hereinafter, a modification example of the second region 7 shall be shown. FIG. 15 corresponds to FIG. and is a cross-sectional view which shows the modification example of the second region 7 which is applied to the first to third embodiments. In FIG. 15, there is shown an example where the second region 7 according to the modification example is applied to the semiconductor device 1A according to the first embodiment, however, the second region 7 according to the modification example is also applicable to the second and third embodiments.

The second region 7 according to the first embodiment is exposed from the first to fourth side surfaces 5A to 5D. In contrast thereto, with reference to FIG. 15, the second region 7 according to the modification example is formed in the surface layer portion of the first main surface 3 (first region 6) at an interval from the first to fourth side surfaces 5A to 5D. That is, the second region 7 exposes the first region 6 from the peripheral edge portion of the first main surface 3. In this embodiment, the outer diode D2 is formed in the outer region 10 at an interval from the first to fourth side surfaces 5A to 5D.

As described above, the same effects as the effects described for the first embodiment can be exhibited even in a case where the second region 7 according to the modification example is applied.

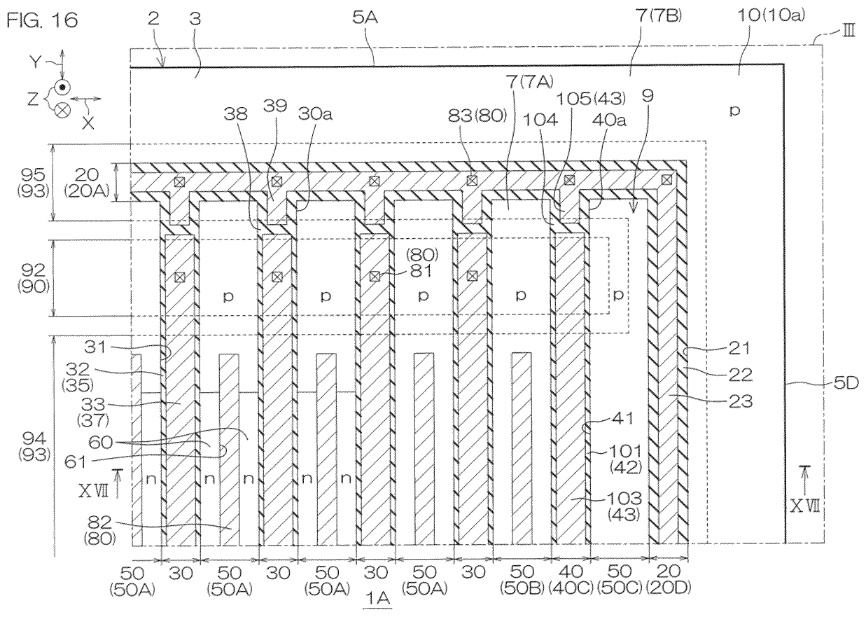

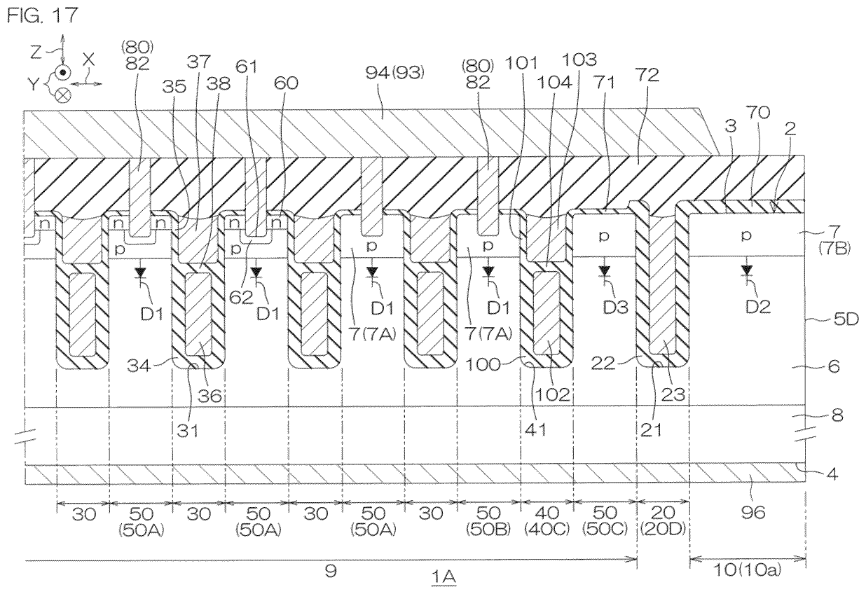

Hereinafter, a modification example of the dummy trench structure 40 shall be shown. FIG. 16 corresponds to FIG. 3 and is a plan view which shows a first modification example of the dummy trench structure 40 applied to the first to third embodiments. FIG. 17 is a cross-sectional view taken alone line XVII-XVII shown in FIG. 16. In FIG. 16 and FIG. 17, there is shown an example where the dummy trench structure 40 according to the first modification example is applied to the semiconductor device 1A according to the first embodiment, however, the dummy trench structure according to the first modification example is also applicable to the second and third embodiments.

The dummy trench structure 40 according to the first embodiment has an inner structure different from an inner structure of the trench separation structure 20 or an inner structure of the trench gate structure 30. In contrast thereto, the dummy trench structure 40 according to the first modification example has the same inner structure as the trench gate structure 30 and has an inner structure different from the trench separation structure 20. Specifically, the dummy trench structure 40 according to the first modification example does not have the embedded insulator 44 but includes the dummy trench 41, the dummy insulating film 42, and the dummy electrode 43. The dummy trench 41, the dummy insulating film 42, and the dummy electrode 43 are formed in the same manner as the gate trench 31, the gate insulating film 32, and the gate electrode 33.

Specifically, the dummy insulating film 42 includes a dummy lower insulating film 100 and a dummy upper insulating film 101 which respectively correspond to the lower insulating film 34 and the upper insulating film 35 of the gate insulating film 32. The dummy electrode 43 includes a dummy lower electrode 102, a dummy upper electrode 103, and a dummy intermediate insulating film 104 which respectively correspond to the lower electrode 36, the upper electrode 37, and the intermediate insulating film 38 of the gate electrode 33. The dummy lower electrode 102 has a plurality of dummy lead-out portions 105 which correspond to the plurality of lead-out portions 39 of the lower electrode 36. The dummy lower electrode 102 (dummy lead-out portion 105) is electrically connected to the separation electrode 23 of the trench separation structure and the dummy upper electrode 103 is formed in an electrically floating state.

As described above, the same effects as the effects described for the first embodiment can be exhibited even in a case where the dummy trench structure 40 according to the first modification example is applied.

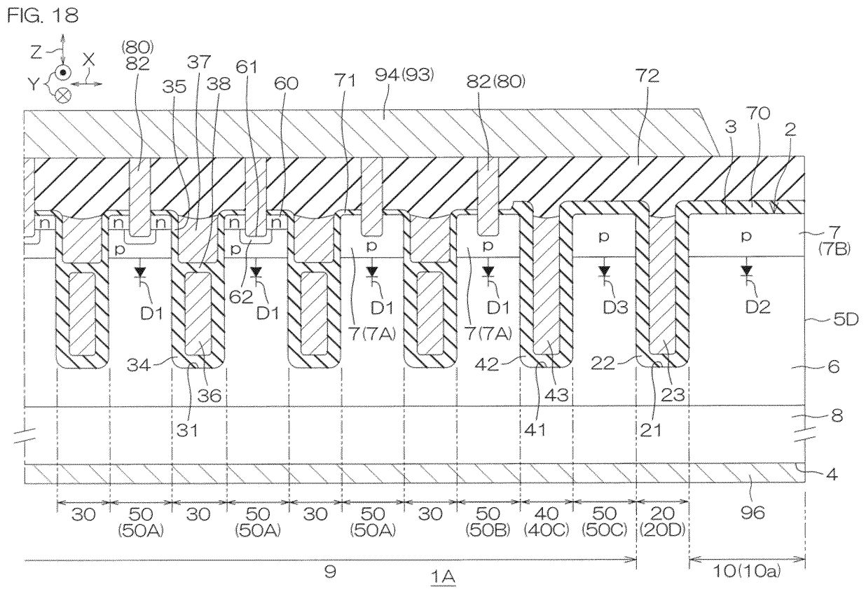

FIG. 18 corresponds to FIG. 5 and is a cross-sectional view which shows a second modification example of the dummy trench structure 40 applied to the first to third embodiments. In FIG. 18, there is shown an example where the dummy trench structure 40 according to the second modification example is applied to the semiconductor device 1A according to the first embodiment, however, the dummy trench structure 40 according to the second modification example is also applicable to the second and third embodiments.

The dummy trench structure 40 according to the second modification example has the same inner structure as the trench separation structure 20 and has an inner structure different from the trench gate structure 30. Specifically, the dummy trench structure 40 according to the second modification example does not have the embedded insulator 44 but includes the dummy trench 41, the dummy insulating film 42, and the dummy electrode 43. The dummy insulating film 42 and the dummy electrode 43 are formed in the same manner as the separation insulating film 22 and the separation electrode 23. A dummy electrode 107 is electrically connected to the separation electrode 23 at a communicating portion of the separation trench 21 and the dummy trench 41.

As described above, the same effects as the effects described for the first embodiment can be exhibited even in a case where the dummy trench structure 40 according to the second modification example is applied.

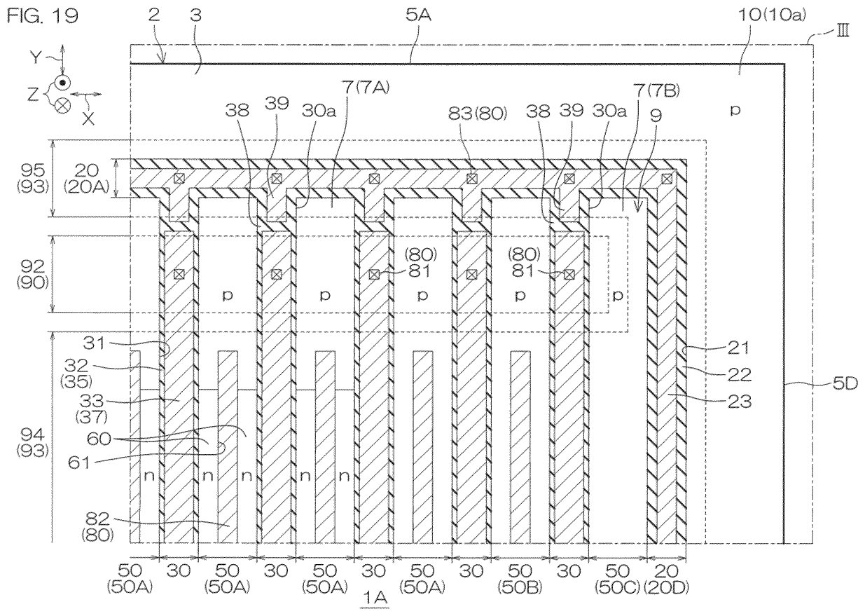

Hereinafter, a modification example of the device region 9 shall be shown. FIG. 19 corresponds to FIG. 3 and is a cross-sectional view which shows the modification example of the device region 9 applied to the first to third embodiments. In FIG. 19, there is shown an example where the device region 9 according to the modification example is applied to the semiconductor device 1A according to the first embodiment, however, the device region 9 according to the modification example is also applicable to the second and third embodiments.

In the device region 9 according to the first embodiment, the plurality of dummy trench structures 40 are formed. In contrast thereto, with reference to FIG. 19, in the device region 9 according to the modification example, the dummy trench structure 40 is not formed. Therefore, the trench gate structure 30 which is the outermost one faces the trench separation structure 20 in the first direction X across one mesa portion 50.

As described above, the same effects as the effects described for the semiconductor device 1A can be exhibited even in a case where the device region 9 according to the modification example is applied.

Each of the above-described embodiments can be executed in still other modes. In each of the above-described embodiments, there is shown an example where the pad region 10b of the outer region 10 (curved portion 9a of device region 9/trench curved portion 20E of trench separation structure 20) is set at the central portion of the third side surface 5C in plan view. However, a arrangement of the pad region 10b (curved portion 9a/trench curved portion 20E) is arbitrary. For example, the pad region 10b (curved portion 9a/trench curved portion may be arranged in a region along an arbitrary corner of the first main surface 3 in plan view.

In each of the above-described embodiments, there is shown an example where the plurality of source regions 60 are formed only at the plurality of first mesa portions 50A but are not formed at the plurality of second and third mesa portions 50B and 50C. However, the plurality of source regions 60 may be formed in one of or both of the plurality of second and third mesa portions 50B and 50C.

In each of the above-described embodiments, a description of an example where the gate wiring electrode 90 made of a member different from the plurality of gate via electrodes 81 is formed has been given. However, a part of the gate wiring electrode 90 may be formed as the plurality of gate via electrodes 81. That is, the gate wiring electrode 90 may include the plurality of gate via electrodes 81 which penetrate through the interlayer insulating film 72.

In each of the above-described embodiments, a description of an example where the source wiring electrode 93 made of a member different from the plurality of first to third source via electrodes 82 to 84 is formed has been given. However, a part of the source wiring electrode 93 may be formed as the plurality of first to third source via electrodes 82 to 84 which penetrate through the interlayer insulating film 72. That is, the source wiring electrode 93 may include the plurality of first to third source via electrodes 82 to 84 which penetrate through the interlayer insulating film 72.

In the above-described second embodiment, there is shown an example where a source potential is to be applied to the lower electrode 26 of the trench gate structure 30. However, a gate potential may be applied to the lower electrode 26 of the trench gate structure 30. In this case, the third source via electrode 84 may be changed to the gate via electrode, and the gate finger electrode 92 may be electrically connected to the gate via electrode. In the case of the above structure, the inner diode D1 and the intermediate diode D3 are electrically separated from the lower electrode 26.

In the above-described second embodiment, there is shown an example where the trench gate structure 30 has a structure different from the trench separation structure 20. However, the trench gate structure 30 may have the same inner structure as the trench separation structure 20 (that is, single electrode structure). In this case, the gate insulating film 32 and the gate electrode 33 are formed in the same manner as the separation insulating film 22 and the separation electrode 23.

In each of the above-described embodiments, a description of an example where the “first conductivity type” is an “n-type” and the “second conductivity type” is a p-type has been given, however, the “first conductivity type” may be a “p-type” and the “second conductivity type” may be an “n-type.” A specific configuration of this case is obtained by replacing the “n-type region” with the “p-type region” and replacing the “p-type region” with the “n-type region” in the above description and attached drawings.

In each of the above-described embodiments, in place of the n-type third region 8, the p-type third region 8 may be adopted. According to this structure, in place of a MISFET, an IGBT (Insulated Gate Bipolar Transistor) can be provided. In this case, a specific configuration can be obtained by replacing a “source (impurity region)” of the MISFET with an “emitter (impurity region)” of the IGBT and replacing a “drain” of the MISFET with a “collector” of the IGBT in the above description.

In each of the above-described embodiments, there is shown an example where the chip 2 includes silicon. However, the chip 2 may be constituted of a WBG (Wide Band Gap) semiconductor chip. The WBG semiconductor is a semiconductor which has a band gap exceeding a band gap of silicon. In this case, the chip 2 may include GaN (gallium nitride), SiC (silicon carbide), diamond, etc., as a WBG semiconductor.

Hereinafter, examples of features extracted from this description and the drawings are shown. Hereinafter, a semiconductor device capable of improving electrical characteristics shall be provided.

[A1] A semiconductor device comprising: a chip which has a main surface; a first region of a first conductivity type which is formed in a surface layer portion of the main surface; a second region of a second conductivity type which is formed in a surface layer portion of the first region; a trench separation structure which penetrates through the second region, surrounds an interior of the second region, and demarcates an inner region at an inner side of the second region and an outer region at an outer side of the second region in the main surface; a trench gate structure which is formed in the inner region so as to penetrate through the second region; an inner diode which includes the first region and the second region that are positioned in the inner region; and an outer diode which includes the first region and the second region that are positioned in the outer region and is electrically separated from the trench gate structure and the inner diode by the trench separation structure.

[A2] The semiconductor device according to A1, wherein the outer diode is constituted of a floating diode which is formed in an electrically floating state.

[A3] The semiconductor device according to A1 or A2, wherein the outer diode surrounds the trench separation structure in plan view.

[A4] The semiconductor device according to any one of A1 to A3, wherein the chip has a side surface, and the outer diode is exposed from the side surface of the chip.

[A5] The semiconductor device according to any one of A1 to A4, wherein the trench gate structure has a multi-electrode structure which includes a lower electrode and an upper electrode that are separated and embedded in an up/down direction inside a gate trench.

[A6] The semiconductor device according to A5, wherein the second region of the inner diode is electrically connected to the lower electrode.

[A7] The semiconductor device according to A5 or A6, wherein a source potential is to be applied to the lower electrode and a gate potential is to be applied to the upper electrode.

[A8] The semiconductor device according to any one of A1 to A7, wherein the trench gate structures are arrayed as a stripe shape in the inner region.

[A9] The semiconductor device according to any one of A1 to A8, wherein the trench separation structure includes a separation electrode which is embedded inside a separation trench.

[A10] The semiconductor device according to A9, wherein the second region of the inner diode is electrically connected to the separation electrode.

[A11] The semiconductor device according to A9 or A10, wherein the trench separation structure has a single electrode structure which includes the single separation electrode.

[A12] The semiconductor device according to any one of A1 to A11, further comprising: an impurity region of the first conductivity type which is formed in a surface layer portion of the second region so as to be in contact with the trench gate structure in the inner region.

[A13] The semiconductor device according to A12, wherein the impurity region is formed at an interval from the trench separation structure so as not to be in contact with the trench separation structure.

[A14] The semiconductor device according to any one of A1 to A13, further comprising: a dummy trench structure which is formed at a region between the trench separation structure and the trench gate structure in the inner region so as to penetrate through the second region and electrically separated from the trench gate structure.

[A15] The semiconductor device according to A14, further comprising: an intermediate diode which includes the first region and the second region positioned in a region between the trench separation structure and the dummy trench structure and is electrically separated from the outer diode by the trench separation structure.

[A16] The semiconductor device according to A15, wherein the intermediate diode is electrically separated from the trench gate structure and the inner diode by the dummy trench structure.

[A17] The semiconductor device according to A16, wherein the intermediate diode is constituted of a floating diode which is formed in an electrically floating state.

[A18] The semiconductor device according to A15, wherein the intermediate diode is electrically connected to the inner diode.

[A19] The semiconductor device according to any one of A14 to A18, wherein the dummy trench structure has an inner structure different from the trench gate structure.

[A20] The semiconductor device according to any one of A14 to A19, wherein the dummy trench structure has an inner structure different from the trench separation structure.

[A21] The semiconductor device according to any one of A14 to A20, wherein the dummy trench structure includes a dummy electrode which is embedded at a bottom side of a dummy trench and an insulator which is embedded at an opening of the dummy trench.

[A22] The semiconductor device according to A21, wherein the dummy trench structure does not include an electrode which faces the dummy electrode across the insulator inside the dummy trench.

[A23] The semiconductor device according to A21 or A22, wherein the insulator covers an entire area of the dummy electrode inside a recess which is demarcated by a side wall of the dummy trench and the dummy electrode.

[B1] A semiconductor device comprising: a chip which has a main surface; a trench separation structure which is formed in the main surface so as to extend in a first direction; a trench gate structure which is formed in the main surface so as to extend in a second direction that intersects the first direction and demarcates a mesa portion with the trench separation structure; a first body region which is formed in a surface layer portion of the main surface inside the mesa portion; and a second body region which is formed in a surface layer portion of the main surface outside the mesa portion and electrically separated from the trench gate structure and the first body region by the trench separation structure.

[B2] The semiconductor device according to B1, wherein the first body region is in contact with the trench gate structure, and the second body region is in contact with the trench separation structure.

[B3] The semiconductor device according to B1 or B2, wherein the second body region is substantially equal in thickness to the first body region.

[B4] The semiconductor device according to any one of B1 to B3, wherein the second body region is formed in an electrically floating state.

[B5] The semiconductor device according to any one of B1 to B4, wherein a source potential is to be imparted to the first body region.

[B6] The semiconductor device according to any one of B1 to B5, wherein the pair of trench separation structures are arrayed in the main surface at an interval in the second direction, and the trench gate structure is formed in a region which is sandwiched between the pair of trench separation structures and demarcates the mesa portion with the pair of trench separation structures.

[B7] The semiconductor device according to B6, wherein the pair of trench gate structures are arrayed at an interval in the first direction in a region sandwiched between the pair of trench separation structures and demarcate the mesa portion with the pair of trench separation structures.

[B8] The semiconductor device according to B6 or B7, wherein the first body region is in contact with the pair of trench separation structures and the trench gate structure inside the mesa portion.

[B9] The semiconductor device according to any one of B6 to B8, wherein the second body region is in contact with one of or both of the pair of trench separation structures outside the mesa portion.

[B10] The semiconductor device according to any one of B1 to B9, wherein the first body region extends as a band shape along the trench gate structure in plan view.

[B11] The semiconductor device according to any one of B1 to B10, wherein the second body region surrounds the trench separation structure and the trench gate structure in plan view.

[B12] The semiconductor device according to any one of B1 to B11, wherein the chip has a side surface, and the second body region is exposed from the side surface.

[B13] The semiconductor device according to any one of B1 to B12, further comprising: a source region which is formed in a surface layer portion of the first body region.

[B14] The semiconductor device according to B13, wherein the source region is not formed in the second body region.

[B15] The semiconductor device according to B13 or B14, wherein the source region is in contact with the trench gate structure but not in contact with the trench separation structure.

[B16] The semiconductor device according to any one of B13 to B15, wherein the source region extends as a band shape along the trench gate structure in plan view.

[B17] The semiconductor device according to any one of B1 to B16, further comprising: a dummy trench structure which is arranged so as to extend in the second direction at an interval from the trench gate structure in the first direction and electrically separated from the trench gate structure.

[B18] The semiconductor device according to B17, wherein the first body region is electrically separated from the dummy trench structure, and the second body region is electrically separated from the dummy trench structure.

[B19] The semiconductor device according to B17 or B18, wherein the dummy trench structure has an inner structure different from the trench gate structure.

[B20] The semiconductor device according to any one of B17 to B19, wherein the dummy trench structure has an inner structure different from the trench separation structure.

[C1] A semiconductor device comprising: a chip which has a main surface; a trench separation structure which is formed in the main surface; a trench gate structure which is formed in the main surface at an interval from the trench separation structure: a dummy trench structure which is formed in the main surface so as to be interposed between the trench gate structure and the trench separation structure and electrically separated from the trench gate structure; an inner diode which is formed in a region between the trench gate structure and the dummy trench structure inside the chip; an intermediate diode which is formed in a region between the trench separation structure and the dummy trench structure inside the chip; and an outer diode which is formed in a region at a side opposite to the dummy trench structure with respect to the trench separation structure inside the chip and electrically separated from the inner diode and the intermediate diode.

[C2] The semiconductor device according to C1, wherein the outer diode is formed in an electrically floating state.

[C3] The semiconductor device according to C1 or C2, wherein the intermediate diode is formed in an electrically floating state.

[C4] The semiconductor device according to C1 or C2, wherein the intermediate diode is electrically connected to the inner diode.

[D1] A semiconductor device (1A, 1B, 1C) comprising: a chip (2) which has a main surface (3); a trench separation structure (20) which demarcates one region (9) and the other region (10) in the main surface (3); a first diode (D1, D3) which is formed inside the one region (9) so as to electrically operate; and a second diode (D2) which is formed inside the other region (10) and electrically separated from the first diode (D1, D3) by the trench separation structure (20).

[D2] The semiconductor device (1A, 1B, 1C) according to D1, wherein the second diode (D2) is formed so as not to electrically operate.

[D3] The semiconductor device (1A, 1B, 1C) according to D1 or D2, wherein the first diode (D1, D3) has a first anode and a first cathode, and the second diode (D2) includes a second anode which is electrically opened and a second cathode which is electrically connected to the first cathode.

[D4] The semiconductor device according to any one of D1 to D3, wherein the first diode (D1, D3) functions as a body diode of a transistor (MISFET).

[D5] The semiconductor device according to any one of D1 to D4, wherein a source potential is to be applied to the trench separation structure (20).

[E1] A semiconductor device (1C) comprising: a chip (2) which has a main surface (3); a first device region (9: 9A to 9D) which is set in the main surface (3); a second device region (9: 9A to 9D) which is set in a region different from the first device region (9: 9A to 9D) in the main surface (3); an outer region (10: 10a, 10b, 10c) which is set in a region between the first device region (9: 9A to 9D) and the second device region (9: 9A to 9D) in the main surface (3); a first diode (D1, D3) which is formed in the first device region (9: 9A to 9D); a second diode (D1, D3) which is formed in the second device region (9: 9A to 9D); and a third diode (D2) which is formed in the outer region (10: 10a, 10b, 10c) and electrically separated from the first diode (D1, D3) and the second diode (D1, D3).

[E2] The semiconductor device (1C) according to E1, wherein the second diode (D1, D3) is electrically connected to the first diode (D1, D3).

[E3] The semiconductor device (1C) according to E1 or E2, wherein the second diode (D1, D3) is operated simultaneously with the first diode (D1, D3).

[E4] The semiconductor device (1C) according to any one of E1 to E3, wherein the third diode (D2) is electrically opened.

[E5] The semiconductor device (1C) according to any one of E1 to E4, wherein the first diode (D1, D3) has a first anode and a first cathode, the second diode (D1, D3) has a second anode which is electrically connected to the first anode and a second cathode which is electrically connected to the first cathode, and the third diode (D2) has a third anode which is electrically opened and a third cathode which is electrically connected to the first cathode and the second cathode.

[E6] The semiconductor device (1C) according to any one of E1 to E5, wherein the outer region (10: 10a, 10b, 10c) surrounds the first device region (9: 9A to 9D) and the second device region (9: 9A to 9D) in plan view, and the third diode (D2) surrounds the first device region (9: 9A to 9D) and the second device region (9: 9A to 9D) in plan view.

[E7] The semiconductor device (1C) according to any one of E1 to E6, wherein the chip (2) has side surfaces (5A to 5D), and the third diode (D2) is exposed from the side surfaces (5A to 5D) of the chip (2).

[E8] The semiconductor device (1C) according to any one of E1 to E7, further comprising: a first transistor (MISFET) which is formed in the first device region (9: 9A to 9D); and a second transistor (MISFET) which is formed in the second device region (9: 9A to 9D), wherein the first diode (D1, D3) is a first body diode of the first transistor (MISFET) and the second diode (D1, D3) is a second body diode of the second transistor (MISFET).

[E9] The semiconductor device (1C) according to E8, wherein the first transistor (MISFET) has first gate structures (30) which are arrayed as a stripe shape extending in one direction and the second transistor (MISFET) has second gate structures (30) which are arrayed as a stripe shape extending in a direction that intersects one direction.

[E10] The semiconductor device (1C) according to E9, wherein the first gate structure (30) is constituted of a first trench gate structure (30) and the second gate structure (30) is constituted of a second trench gate structure (30).

[E11] The semiconductor device (1C) according to any one of E1 to E10, further comprising: a trench separation structure (20) which is formed in the main surface (3) so as to demarcate the outer region (10: 10a, 10c) from the first device region (9: 9A to 9D) and the second device region (9: 9A to 9D).

Although alphanumeric characters within parentheses according to the aforementioned [D1] to [D5] and the aforementioned [E1] to [E11] express corresponding constitutes, etc., in the above-described embodiments, these are not meant to limit the scopes of respective items to the embodiments. While the embodiments of the present invention have been described in detail, these are merely specific examples used to clarify the technical contents of the present invention and the present invention should not be interpreted as being limited to these specific examples, and the scope of the present invention is to be limited by the appended claims.

What is claimed is:

1. A semiconductor device comprising:
a chip which has a main surface;
a first region of a first conductivity type which is formed in a surface layer portion of the main surface;
a second region of a second conductivity type which is formed in a surface layer portion of the first region;
a trench separation structure which penetrates through the second region, surrounds an interior of the second region, and demarcates an inner region at an inner side of the second region and an outer region at an outer side of the second region in the main surface;
a trench gate structure which is formed in the inner region so as to penetrate through the second region;
an inner diode which includes the first region and the second region that are positioned in the inner region; and
an outer diode which includes the first region and the second region that are positioned in the outer region and is electrically separated from the trench gate structure and the inner diode by the trench separation structure.

2. The semiconductor device according to claim 1,
wherein the outer diode is constituted of a floating diode which is formed in an electrically floating state.

3. The semiconductor device according to claim 1,
wherein the outer diode surrounds the trench separation structure in plan view.

4. The semiconductor device according to claim 1,
wherein the chip has a side surface, and
the outer diode is exposed from the side surface of the chip.

5. The semiconductor device according to claim 1,
wherein the trench gate structure has a multi-electrode structure which includes a lower electrode and an upper electrode that are separated and embedded in an up/down direction inside a gate trench, and
the second region of the inner diode is electrically connected to the lower electrode.

6. The semiconductor device according to claim 1,
wherein the trench gate structures are arrayed as a stripe shape in the inner region.

7. The semiconductor device according to claim 1,
wherein the trench separation structure includes a separation electrode which is embedded inside a separation trench, and
the second region of the inner diode is electrically connected to the separation electrode.

8. The semiconductor device according to claim 7,
wherein the trench separation structure has a single electrode structure which includes the single separation electrode.

9. The semiconductor device according to claim 1, further comprising:
an impurity region of the first conductivity type which is formed in a surface layer portion of the second region so as to be in contact with the trench gate structure in the inner region.

10. The semiconductor device according to claim 9,
wherein the impurity region is formed at an interval from the trench separation structure so as not to be in contact with the trench separation structure.

11. The semiconductor device according to claim 1, further comprising:
a dummy trench structure which is formed at a region between the trench separation structure and the trench gate structure in the inner region so as to penetrate through the second region and electrically separated from the trench gate structure.

12. The semiconductor device according to claim 11, further comprising:
an intermediate diode which includes the first region and the second region positioned in a region between the trench separation structure and the dummy trench structure and is electrically separated from the outer diode by the trench separation structure.

13. The semiconductor device according to claim 11,
wherein the dummy trench structure has an inner structure different from the trench gate structure.

14. The semiconductor device according to claim 1,
wherein the dummy trench structure has an inner structure different from the trench separation structure.

15. The semiconductor device according to claim 1,
wherein the dummy trench structure includes a dummy electrode which is embedded at a bottom side of a dummy trench and an insulator which is embedded at an opening side of the dummy trench.

16. The semiconductor device according to claim 15,
wherein the dummy trench structure does not include an electrode which faces the dummy electrode across the insulator inside the dummy trench.

17. A semiconductor device comprising:
a chip which has a main surface;
a trench separation structure which is formed in the main surface so as to extend in a first direction;
a trench gate structure which is formed in the main surface so as to extend in a second direction that intersects the first direction and demarcates a mesa portion with the trench separation structure;
a first body region which is formed in a surface layer portion of the main surface inside the mesa portion; and
a second body region which is formed in a surface layer portion of the main surface outside the mesa portion and electrically separated from the trench gate structure and the first body region by the trench separation structure.

18. The semiconductor device according to claim 17,
wherein a source potential is to be imparted to the first body region, and
the second body region is formed in an electrically floating state.

19. The semiconductor device according to claim 17,
wherein the pair of trench separation structures are arrayed in the main surface at an interval in the second direction,
the trench gate structure is formed in a region which is sandwiched between the pair of trench separation structures and demarcates the mesa portion with the pair of trench separation structures, and
the second body region is in contact with both of the pair of trench separation structures outside the mesa portion.

20. The conductor device according to claim 17,
wherein the chip has a side surface, and
the second body region is exposed from the side surface.
